(19) United States
(12) Patent Application Publication
(10) Pub. No.: US 2017/0206707 A1
(43) Pub. Date: Jul. 20, 2017

(54) VIRTUAL REALITY ANALYTICS PLATFORM

(71) Applicants: Anthony Guay, Montreal (CA); Samuel Forcier-Poirier, Montreal (CA); Kévin Ouellet, Montreal (CA); Pierre Cliche, JR., Montreal (CA); Patrice Robitaille, Beauharnois (CA); Sun Boisvert Knudsen, Montreal (CA)

(72) Inventors: Anthony Guay, Montreal (CA); Samuel Forcier-Poirier, Montreal (CA); Kévin Ouellet, Montreal (CA); Pierre Cliche, JR., Montreal (CA); Patrice Robitaille, Beauharnois (CA); Sun Boisvert Knudsen, Montreal (CA)

(21) Appl. No.: 14/997,187

(22) Filed: Jan. 15, 2016

(51) Int. Cl. G06T 19/00; G06F 3/01; G06T 11/20; G06F 17/30; H03M 7/30

(52) U.S. Cl. CPC G06T 19/006; G06F 17/30327; H03M 7/60; G06T 11/206; G06F 3/012

(57) ABSTRACT

Systems and methods are presented for retrieving, by a server computer, raw data received from one or more client devices; aggregating, by the server computer, the raw data to create aggregated raw data; adding, by the server computer, the aggregated raw data to previously aggregated data; generating, by the server computer, heat map data from the aggregated data; compressing, by the server computer, the heat map data; and storing, by the server computer, the compressed heat map data.

### TECHNICAL FIELD

The present disclosure relates generally to a mechanism for collecting, storing, and analyzing virtual reality data.

### BACKGROUND

Virtual reality technology is starting to be incorporated into headsets (e.g., head-mounted displays) and some gaming applications. But the technology is still lacking a core infrastructure to enable the technology to become more mainstream.

### BRIEF DESCRIPTION OF THE DRAWINGS

Various ones of the appended drawings merely illustrate example embodiments of the present disclosure and should not be considered as limiting its scope.

FIG. 1 is a block diagram illustrating a networked system, according to some example embodiments, to collect, store, and analyze virtual reality data.

FIG. 2 is a block diagram illustrating one example embodiment of a virtual reality application, according to some example embodiments.

FIG. 3 is a block diagram illustrating example analytics servers, according to some example embodiments.

FIG. 4 is a block diagram illustrating one example embodiment of a virtual reality application editor, according to some example embodiments.

FIG. 5 is a flowchart illustrating aspects of a method, according to some example embodiments, for creating a new analytics account.

FIG. 6 is a flowchart illustrating aspects of a method, according to some example embodiments, for acquiring data in a virtual reality application.

FIG. 7 is a flowchart illustrating aspects of a method, according to some example embodiments, for receiving and processing data from an analytics recorder plugin.

FIG. 8A is an example user interface, according to some example embodiments, for creating a new analytics account.

FIG. 8B is an example user interface, according to some example embodiments, for adding an application to an analytics account.

FIGS. 9A-9C show example dashboards, according to some example embodiments.

FIG. 10 shows a user head-mounted display (HMD) position/orientation, according to some example embodiments.

FIG. 11 is a flowchart illustrating aspects of a method, according to some example embodiments, for generating heat map data.

FIG. 12A shows an example hierarchical structure for a virtual world heat map, according to some example embodiments.

FIG. 12B shows how a direction from a center of a sphere is translated to a two dimensional matrix, according to some example embodiments.

FIG. 12C shows an example hierarchical structure for a sight heat map, according to some example embodiments.

FIG. 12D shows example four matrix arrays, according to some example embodiments

FIGS. 12E(1) and 12E(2) show an incorrect depth projection and a correct depth projection, according to some example embodiments.

FIG. 12F shows an example octree representation of a positional heat map frame, according to some example embodiments.

FIG. 12G shows an example matrix of a frame of a sight heat map, according to some example embodiments.

FIG. 13 is a flow chart illustrating aspects of a method, according to some example embodiments, for converting heat map data into a heat map.

FIG. 14A shows an example interface for importing a heat map player plugin, according to some example embodiments.

FIG. 14B shows an example interface showing a heat map menu item access, according to some example embodiments.

FIG. 14C shows an example application identifier and application key, according to some example embodiments.

FIG. 14D shows an example frame of pixels, according to some example embodiments.

FIG. 14E shows an example heat map, according to some example embodiments.

FIG. 14F shows an example sphere in a scene, according to some example embodiments.

FIGS. 14G(1) and 14G(2) show heat map images added to intern faces of a sphere, according to some example embodiments.

FIG. 14H shows the results of a cubemap technique, according to some example embodiments.

FIG. 14I shows an example equirectangular image, according to some example embodiments.

FIG. 14J shows an example user interface, according to some example embodiments.

FIG. 15A illustrates an example movement of an HMD, according to some example embodiments.

FIG. 15B illustrates an example movement of one user onto a frame, according to some example embodiments.

FIG. 15C shows an example aggregation of users recordings onto a single set of frames, according to some example embodiments.

FIG. 15D shows an example representation of a heat map with colors, according to some example embodiments.

FIG. 15E illustrates an example stack of heat map frames representing a heat map video, according to some example embodiments.

FIG. 16 is a block diagram illustrating an example of a software architecture that may be installed on a machine, according to some example embodiments, configured to collect, store, and process virtual reality application data to generate analytics.

FIG. 17 illustrates a diagrammatic representation of a machine, in the form of a computer system, within which a set of instructions may be executed for causing the machine to perform any one or more of the methodologies discussed herein, according to an example embodiment.

### DETAILED DESCRIPTION

Systems and methods described herein relate to collecting, storing, and processing virtual reality application and head-mounted display (HMD) data to provide analytics to users such as developers and advertisers.

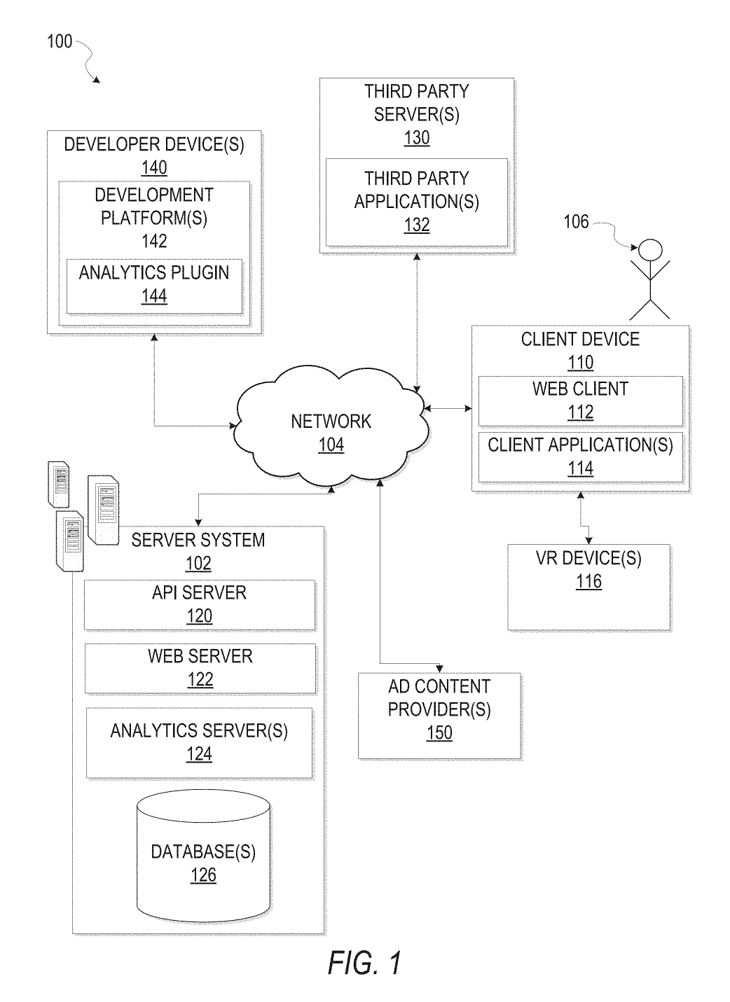

FIG. 1 is a block diagram illustrating a networked system 100, according to some example embodiments, configured to collect, process, and generate analytics for virtual reality applications. The system 100 may include one or more client devices such as client device 110. The client device 110 may comprise, but is not limited to, a mobile phone, desktop computer, laptop, portable digital assistants (PDAs), smart phones, tablets, ultra books, netbooks, laptops, multi-processor systems, microprocessor-based or programmable consumer electronics, game consoles, set-top boxes, computers in vehicles, or any other communication device that a user may utilize to access the networked system 100. In some embodiments, the client device 110 may comprise a display module (not shown) to display information (e.g., in the form of user interfaces). In further embodiments, the client device 110 may comprise one or more of touch screens, accelerometers, gyroscopes, cameras, microphones, global positioning system (GPS) devices, and so forth.

The client device 110 may be a device of a user 106 that is used to play virtual reality games or interact with other virtual reality applications. One or more users 106 may be a person, a machine, or other means of interacting with the client device 110. In example embodiments, the user 106 may not be part of the system 100, but may interact with the system 100 via the client device 110 or other means. For instance, the user 106 may provide input (e.g., touch screen input or alphanumeric input) to the client device 110 and the input may be communicated to other entities in the system 100 (e.g., third party server(s) 130, server system 102, etc.) via the network 104. In this instance, the other entities in the system 100, in response to receiving the input from the user 106, may communicate information to the client device 110 via the network 104 to be presented to the user 106. In this way, the user 106 may interact with the various entities in the system 100 using the client device 110.

The system 100 may further include a network 104. One or more portions of the network 104 may be an ad hoc network, an intranet, an extranet, a virtual private network (VPN), a local area network (LAN), a wireless LAN (WLAN), a wide area network (WAN), a wireless WAN (WWAN), a metropolitan area network (MAN), a portion of the Internet, a portion of the Public Switched Telephone Network (PSTN), a cellular telephone network, a wireless network, a WiFi network, a WiMax network, another type of network, or a combination of two or more such networks.

The client device 110 may access the various data and applications provided by other entities in the system 100 via a web client 112 (e.g., a browser, such as the Internet Explorer® browser developed by Microsoft® Corporation of Redmond, Wash. State) or one or more client applications 114. The client device 110 may include one or more applications 114 (also referred to as “apps”) such as, but not limited to, a web browser, messaging application, electronic mail (email) application, an e-commerce site application, virtual reality application, and the like. In some embodiments, one or more applications 114 may be included in a given one of the client device 110, and configured to locally provide the user interface and at least some of the functionalities with the application(s) 114 configured to communicate with other entities in the system 100 (e.g., third party server(s) 130, server system 102, etc.), on an as needed basis, for data and/or processing capabilities not locally available (e.g., to authenticate a user 106, to verify a method of payment, load additional data, etc.). Conversely, one or more applications 114 may not be included in the client device 110, and then the client device 110 may use its web browser to access the one or more applications 114 hosted on other entities in the system 100 (e.g., third party server(s) 130, server system 102, etc.).

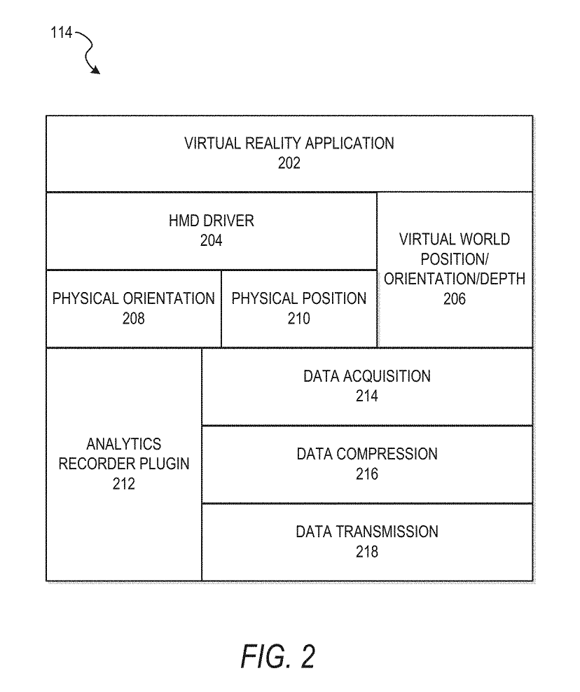

In one embodiment, a client application 114 may be a virtual reality application 202 as shown in FIG. 2. A virtual reality application 202 may be created by an application developer (e.g., a company or one or more individuals). For example, a virtual reality application 202 may be a game (e.g., a first person shooter game), a simulation (e.g., a flight simulator), an experience (e.g., a 360 degree video of a concert), etc. The virtual reality application 202 may include a driver for virtual reality (VR) device 116, such as a head-mounted display (HMD) driver 204. The HMD driver 204 may be a plugin added to the virtual reality application in the development phase by the developer (e.g., using a virtual reality application editor). A plugin may be a third party module which is used in combination with existing software to extend an application functionality. The HMD driver 204 may be provided by the HMD manufacturer.

The HMD driver 204 may communicate between the HMD's sensors (e.g., gyroscope, accelerometer) and the virtual reality application to determine a head position of the user 106 and in which direction the user 106 is looking (e.g., physical orientation 208 and physical position 210). From this information, the virtual reality application 202 is able to know the correct images to display in the HMD relative to the head position/orientation. The information related to physical orientation 208 and physical position 210 may be called physical world coordinates because this information gives the position/orientation of the head of the user 106 in the real (physical) world. In some cases, an HMD may not have a positional sensor(s), and so the only available data would be physical orientation 208; the position of the user's head would be considered fixed in the real (physical) world.

The virtual reality application 202 may also include an analytics recorder plugin 212. This may be a plug-in used to record data from the HMD sensor(s) (e.g., utilizing data from the HMD driver 204), compress the data, and send the data to the server system 102 (e.g., to one or more analytics server(s) 124). Accordingly, the analytics recorder plugin 212 may have three layers. A first layer may be a data acquisition layer 214. The data acquisition layer 214 may be responsible for grabbing the data from the HMD position and/or orientation sensor and position/orientation of the virtual avatar in the virtual world. The data acquisition layer 214 may also record the virtual world position/orientation of the avatar and depth 206 (e.g., distance) of the virtual objects the user 106 sees in the center of the HMD screen. The depth information may be used to calculate a more precise heat map, as described later below.

A second layer of the analytics recorder plugin 212 may be a data compression layer 216. The data compression layer 216 may be responsible for compressing the data before sending it to the server system 102. Compression may be used to compress data for more efficient transmission on the network 104. Some examples of compression and decompression algorithms that may be used to obtain a good compression ratio, and that are fast to compute, include differential coding (lossless), linear quantification (lossy), and non-linear quantification (Lossy).

A third layer of the analytics recorder plugin 212 may be a data transmission layer 218. This layer 218 may be responsible for sending data to the server system 102 (e.g., to one or more analytics server(s) 124). For example, it may take the compressed data and send it to the nearest analytics server 124.

Returning to FIG. 1, a server system 102 may provide server-side functionality via the network 104 (e.g., the Internet or wide area network (WAN)) to one or more third party servers 130 and/or one or more client devices 110, and/or one or more developer device(s) 140. For example, the server system 102 may provide a software development kit (SDK) and/or analytics plugin 144 to be included in one or more development platform(s) 142 on the developer device(s) 140.

The server system 102 may include an application program interface (API) server 120, a web server 122, and one or more analytics server(s) 124 that may be communicatively coupled with one or more databases 126. Database(s) 126 may be storage devices that store information such as HMD data, virtual reality application data, processed data, analytics data, etc.

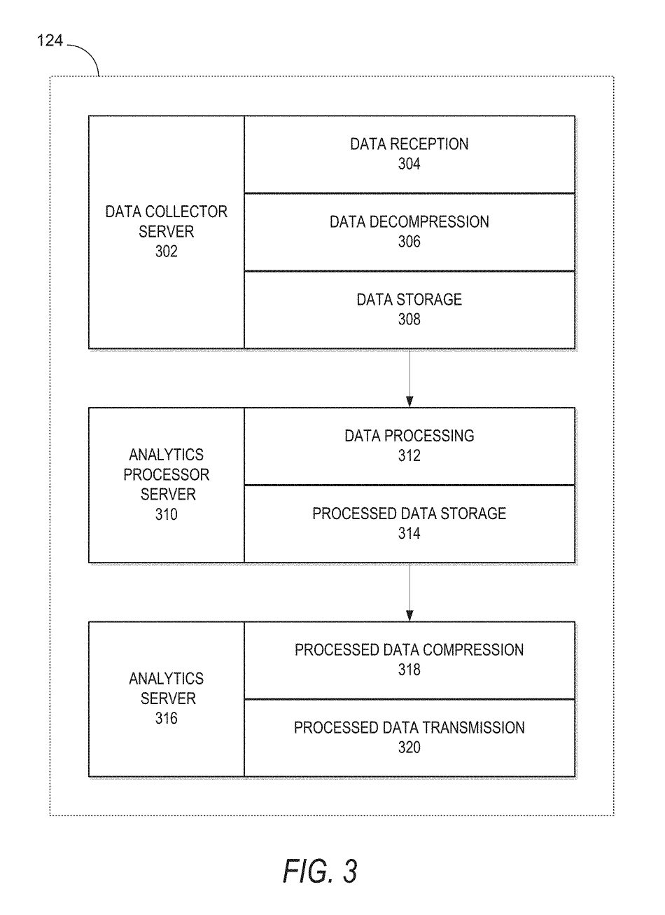

The one or more analytics server(s) 124 may be responsible for receiving raw data from the analytics plugin 144, processing the raw data into usable form, and providing the data to an end user (e.g., via a user interface on a website or in an application). The analytic server(s) 124 may comprise several servers. Some example servers are shown in FIG. 3.

Data collected by the analytics plugin 144 may be sent to the nearest analytics server 124, such as data collector server 302, for temporary storage. For example, a connection may be requested by the analytics plugin 144 to a load balancer and redirected to the nearest and least busy server for data collection. The data collector server 302 may comprise three layers. A first layer data reception 304 may receive data from a client device 110 via an analytics recorder plugin 212. In one example embodiment there may be a plurality of client devices 110 and analytics recorder plugins 212, and thus, the data collector server 302 may receive and store data from a plurality of client devices 110. The data decompression layer 306 then decompresses the data and sends it to appropriate server storage, such as one or more databases 126. The data storage layer 308 then stores the raw data (unprocessed), waiting to be processed by the analytics processor server 310 into analytical data (e.g., graphical presentation such as charts, heat maps, etc.).

The raw data may be processed to be provided to a user (e.g., developer, advertiser, etc.) or to be provided to a heat map player as explained in further detail later below. The analytics processor server 310 may be responsible for processing the raw data. This may be implemented by a scheduled task which may periodically (e.g., every few seconds, minutes, hours, etc.) process new data and add it to the already processed data. The analytics processor server 310 may include two layers.

A first layer may be a data processing layer 312 that processes the data into analytics to be viewed by a user. In one example embodiment, the raw data for all sessions of a scene in a virtual reality application may be aggregated into a heat map data structure (described in detail below). Raw data may be removed from storage after it is processed. New data may be added to the existing processed data without unnecessarily processing the existing data. A second layer may be a processed data storage layer 314, which may be responsible for storing the processed data.

An analytics server 316 may then provide the processed data to a user. For example, the analytics server 316 can make the processed data available to be accessed via a graphical user interface to display graphs, charts, heat maps, videos, etc. to a user. A web browser or other application can access the stored processed data to display it to a user. In addition or in the alternative, the analytics server 316 may include two layers for compressing and sending the data (e.g., to a heat map player plugin in a virtual reality application editor). A first layer may be a processed data compression layer 318 to compress the processed data, and then a second layer, the processed data transmission layer 320, may send the data to an application such as a virtual reality application editor to be displayed to a user via an analytics plugin 144 (e.g., an analytics player plugin 404 to play/display heat map data).

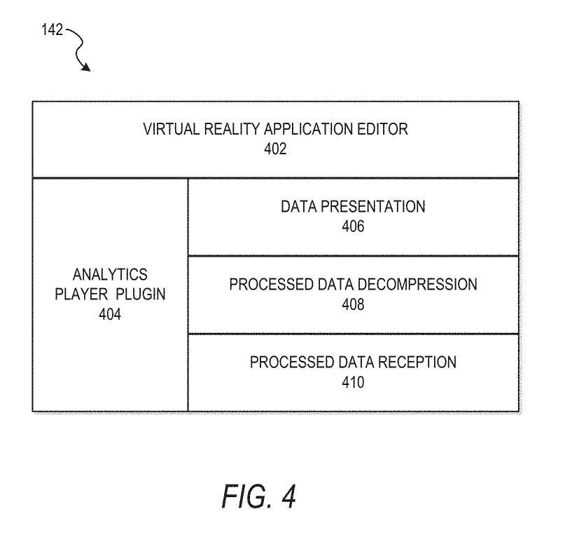

Returning to FIG. 1, the system 100 may include one or more developer device(s) 140. The developer device(s) 140 may also be a client device 110 as explained above. The developer device(s) 140 may include one or more development platform(s) 142 that may include one or more analytics plugin(s) 144. For example, the development platform(s) 142 may be a virtual reality application editor 402 (FIG. 4). The virtual reality application editor 402 may be software used by a developer to create a virtual reality application (e.g., virtual reality application 202). For example, the virtual reality application editor 402 may be a game engine editor with an SDK to use a specific virtual reality peripheral (e.g., HMD) provided by a manufacturer (e.g., Oculus PC SDK). Some examples of game or simulation virtual reality editors include Unity Engine and Unreal Engine. The development platform(s) 142 may include one or more analytics plugin 144.

In one example, the development platform(s) 142 may be a virtual reality application editor 402 as shown in FIG. 4. The virtual reality application editor 402 may include an analytics player plugin 404. The analytics player plugin 404 may be used in the virtual reality application editor 402 to display analytics data to the user (e.g., developer). For example, the analytics player plugin 404 may be used to display a heat map to the developer in relation to virtual reality assets. Virtual reality assets correspond to the virtual reality application experience (e.g., a 3D representation of a building, a virtual table, virtual sounds, etc.). The static element of a scene (e.g., 3D elements that do not move, such as a floor, a building, etc.) may be used to put a layered heat map on top of it.

The analytics player plugin 404 may be a heat map player that is used to superimpose a visualization of heat map data onto the 31) scene representation of the scene. The analytics player plugin 404 may be composed of three major layers. A first layer may be a processed data reception layer 410 to request and receive compressed heat map data. A second layer may be a processed data decompression layer 408 to decompress the heat map data. A third layer may be a data presentation layer 406 to use the decompressed data to present a heat map to a user. A special graphical user interface may be used, in combination with the virtual reality application editor 402 interface, to present heat map information about a position and sight of all users for a particular scene. More details about heat map presentation are described below.

Returning to FIG. 1, one or more third party server(s) 130 may be associated with the one or more developer device(s) 140. For example, one or more third party servers 130 may be associated with a developer of a virtual reality game. The one or more third party servers 130 may include one or more third party application(s) 132 (e.g., virtual reality applications) that may be provided to client devices 110. The one or more developer device(s) 140 may interact with the one or more third party server(s) 130 to provide a new or updated third party application, to receive various data needed for developing such application, etc.

The one or more third party application(s) 132, executing on third party servers) 130, may interact with the server system 102 via API server 120 via a programmatic interface provided by the API server 120. For example, one or more the third party applications 132 may request and utilize information from the server system 102 via the API server 120 to support one or more features or functions on a website hosted by the third party or an application hosted by the third party. The third party website or application(s) 132, for example, may provide virtual reality application and advertising analytics to users that are supported by relevant functionality and data in the server system 102.

The system 100 may include ad content provider(s) 150 that provide various advertising content that may be utilized by server system 102 and/or third party server(s) 130 or developer device(s) 140 and displayed to users on a client device 110 (e.g., during use of one or more client applications 114).

The system 100 may also include one more virtual reality (VR) devices 116. The one or more VR devices 116 may be coupled with a client device 110 or may itself be a client device 110 (e.g., may be a standalone VR device 116). In one example embodiment, the VR device(s) 116 may be a head mounted display (HMD). The VR device(s) 116 may include sensors, such as a gyroscope, an accelerometer, and a magnetometer. The sensors (e.g., gyroscope, accelerometer, and magnetometer) may be used in combination to determine an HMD orientation. A positional sensor (e.g., infrared camera or electro-magnetic trackers) may be used to determine the position in space of the HMD.

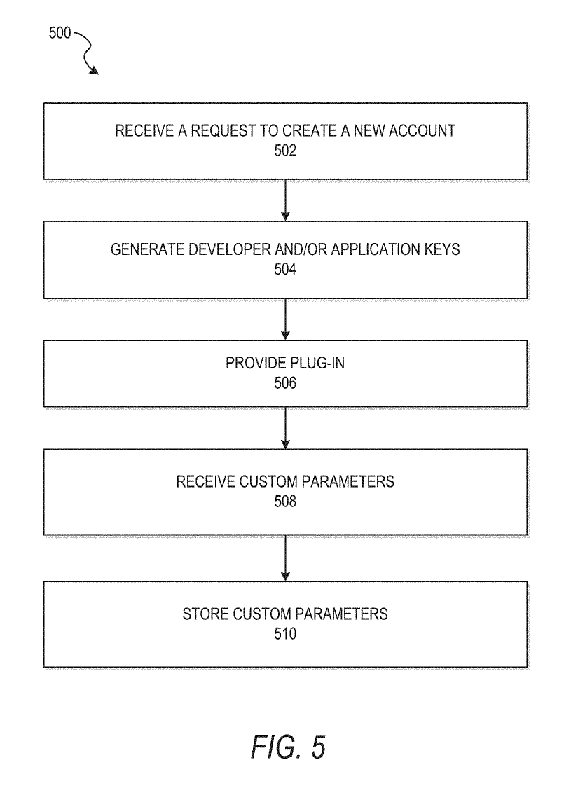

FIG. 5 is a flow chart illustrating aspects of a method 500, according to some example embodiments, for a user to register and create a new account for generating and accessing virtual reality application analytics. For illustrative purposes, method 500 is described with respect to the networked system 100 of FIG. 1. It is to be understood that method 500 may be practiced with other system configurations in other embodiments.

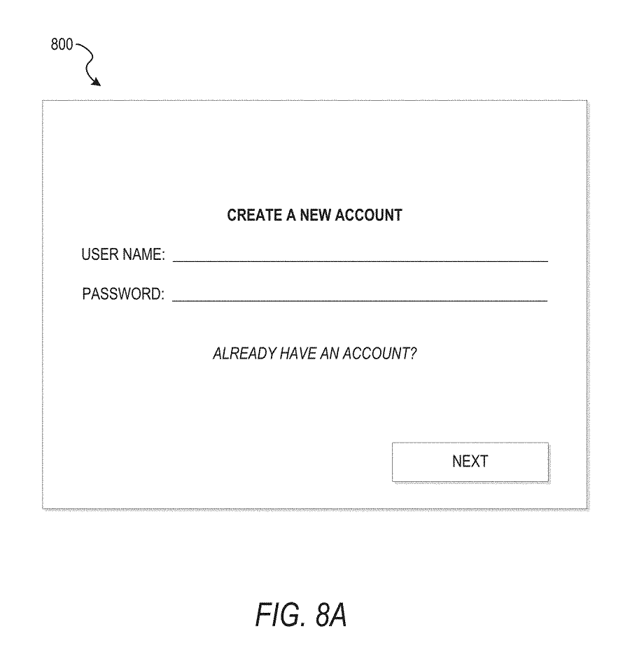

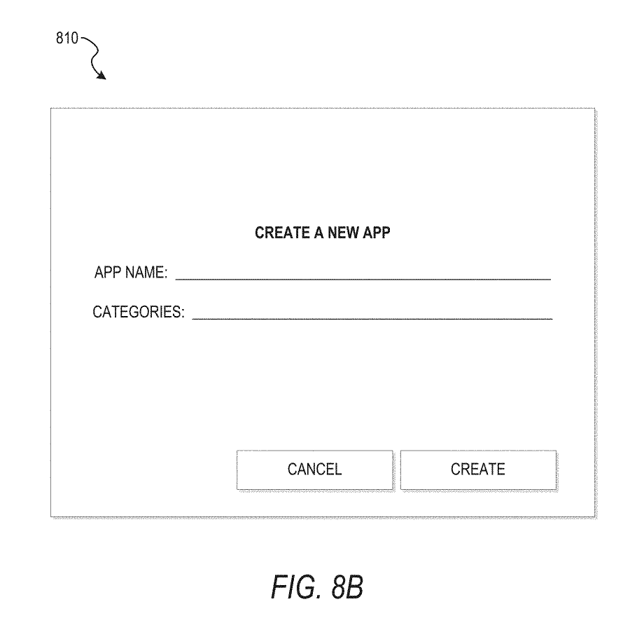

A user, such as a developer of virtual reality applications, may register to create a new account to generate and receive analytics associated with one or more applications that the developer is creating or has created. In one example, the developer may access a particular website or application to create a new account. The developer may provide a user name and password as shown in the example user interface 800 in FIG. 8A.

Once the user submits the new account information, the server system 102 may receive a request from the user to create a new account at operation 502 (e.g., via web server 122 or analytics server(s) 124). Each developer registered with the system may be associated with a unique developer key. And each application that the developer creates may be associated with a unique application key. At operation 504 the analytics server(s) 124 may generate new developer and/or new application keys. The analytics server(s) 124 may store the developer key, the one or more application keys, and other registration information, in one or more databases 126. The analytics server(s) 124 may then provide the user with an SDK or an analytics recorder plugin (e.g., analytics recorder plugin 212), at operation 506. For example, the user may be given an option to download the plugin from the application or website.

Once the analytics recorder plugin is downloaded, the user may insert or import the plugin into the development platform that he is using to develop an application. For example, he may drag and drop the plugin into a virtual reality application editor that he is using to create the virtual reality application. The developer key and application key may also be inserted into the application either by the user or automatically with the plugin. The developer can then compile the application, including the plugin, and provide the application with the plugin to one or more users. The developer key and application key in the plugin will be used to track the data from the application and associate it with the right developer and application when the raw data is received at the analytics server(s) 124. The plugin may automatically record/acquire user data, application data, client device data, HMD data, etc. when a user is using the application.

The developer may add as many applications as desired. To add a new application, he may be presented with a user interface 810 such as the one shown in FIG. 8B. The developer may include an application name and categories associated with the application. When the developer submits the information, the analytics server 124 may create a new application key for the new application.

A variety of parameters may be tracked by the plugin. For example, the plugin may collect hardware information for the client device 110. This may include information about the client device 110 such as the make and model of the device, graphics card information, processor information, IP address, etc. This may also include application information, such as RAM consumption used by the application, number of images per second generated by the application (e.g., frame per second (FPS)), etc. The plugin may also track information about the VR device 116, such as make and model of the device, etc. The plugin may also collect user data such as a user name, profile, contact information, etc. The plugin may also collect HMD data indicating user behavior data such as where the user is looking most, where the user is moving within the application, and other user data, such as how long the user is using the application (e.g., playing a game), etc.

In addition to the parameters tracked by the plugin, the developer may optionally provide custom parameters that the developer would like to have tracked in the application. For example, the application may be a shooting game and the developer may want to track how many bullets users shoot per game. The developer can specify additional custom parameters and submit them to the analytics server 124. At operation 508 the analytics server 124 may receive the custom parameters and, at operation 510, the analytics server 124 may store the custom parameters in one or more databases 126.

The plugin may be updated periodically to include new functionality or to include developer-provided custom parameters, etc. For example, the plugin may be updated when the developer next provides a software update for the application. In another example, the plugin itself may check for updates when the application starts by communicating with server system 102. If there are updates available, the plugin can update in the background and then start monitoring and acquiring data with the new version.

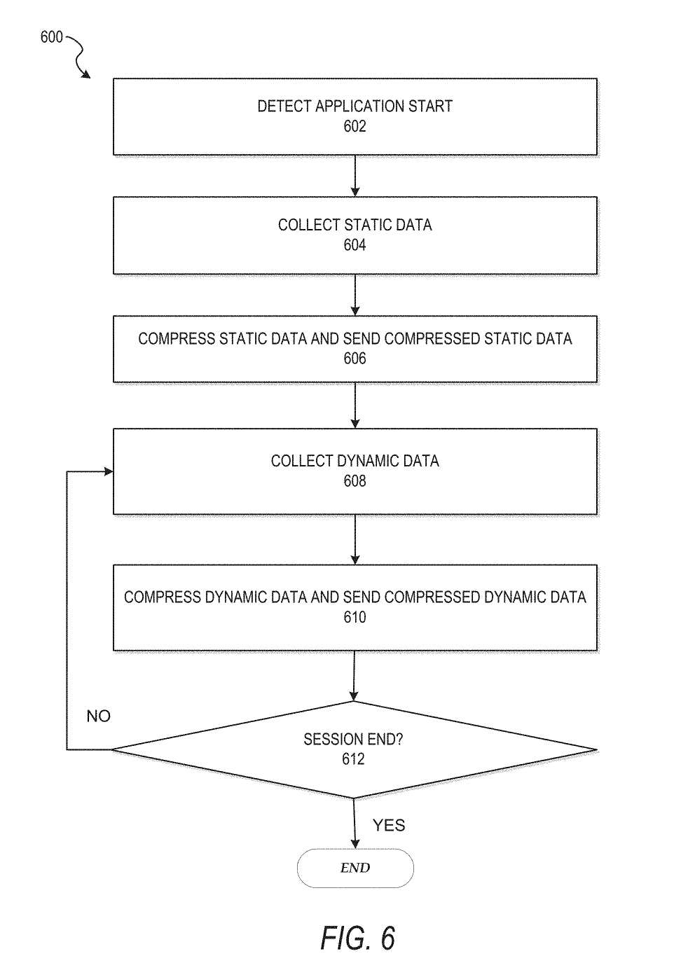

FIG. 6 is a flow chart illustrating aspects of a method 600, according to some example embodiments, for acquiring data in a virtual reality application. For illustrative purposes, method 600 is described with respect to the networked system 100 of FIG. 1, the virtual reality application 202 of FIG. 2, and the virtual reality application editor 402 of FIG. 4. It is to be understood that method 600 may be practiced with other system configurations in other embodiments.

At operation 602, a plugin (e.g., an analytics recorder plugin 212) in the application may detect that an application has started and may start tracking predefined parameters automatically. The plugin 212 may first collect static data at operation 604. For example, the plugin 212 may first collect data that may not change over the use of the application, such as information of the client device 110 (e.g., make and model, graphics card, processor, IP address, etc.), information about the VR device (e.g., make and model, etc.), user data (e.g., user name, profile, contact information, etc.), etc. At operation 606, the analytics recorder plugin 212 may then compress the static data and send the compressed static data to an analytics server 124 (e.g., data collector server 302).

At operation 608, the analytics recorder plugin 212 may start collecting dynamic data. For example, the analytics recorder plugin 212 may collect information that is changing over the use of the application, such as RAM consumption used by the application, number of images per second generated by the application (e.g., frame per second (FPS)), user behavior data, such as where the user is looking most, where the user is moving within the application, how long the user is playing, etc. The analytics recorder plugin 212 may also collect HMD sensor data, as explained in further detail below.

At operation 610, the analytics recorder plugin 212 may compress the dynamic data and send the compressed data at predetermined time intervals (e.g., every 5 seconds, every 1 minute, etc.) to an analytics server 124 (e.g., data collector server 302). The analytics recorder plugin 212 may continue operations 608-610 of collecting dynamic data, compressing and sending compressed dynamic data at predetermined time intervals, until the user is finished using the application. For example, the analytics recorder plugin 212 may determine whether the session has ended at operation 612. If the session has ended (e.g., the user has finished using the application), then the process ends and the analytics recorder plugin 212 may send any additional information collected. If the session has not ended, then the analytics recorder plugin 212 may continue collecting dynamic data at operation 608.

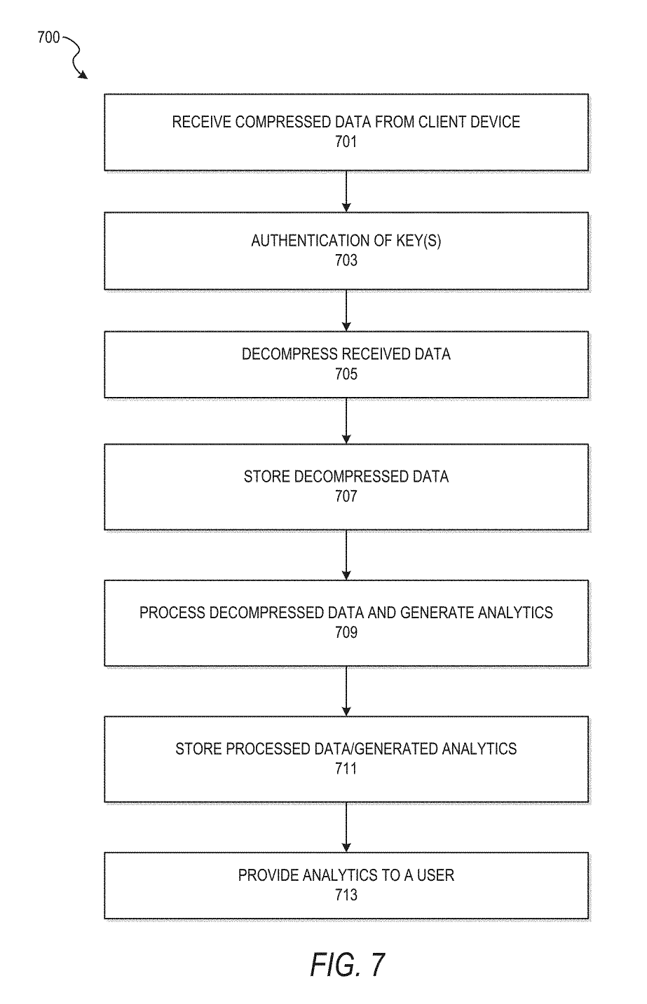

FIG. 7 is a flow chart illustrating aspects of a method 700, according to some example embodiments, for receiving and processing data from the analytics recorder plugin 212. For illustrative purposes, method 700 is described with respect to the networked system 100 of FIG. 1. It is to be understood that method 700 may be practiced with other system configurations in other embodiments.

At operation 701, a server computer (e.g., analytics server 124) may receive compressed data from a client device 110. For example, the client device 110 may send compressed application data, as described above. The compressed application data may include a developer key and an application key. At operation 703, the analytics server 124 may authenticate the client device data using the developer key and application key. For example, the analytics server 124 may look up the developer key and application key in one or more databases 126 to determine that the keys are legitimate keys, etc.

Once the analytics server 124 has completed authentication, the analytics server 124 may decompress the received data at operation 705. The analytics server 124 may then store the decompressed data at operation 707. The analytics server 124 may receive data from a plurality of client devices, and the data may be associated with a plurality of developers and a plurality of applications. As the data is received, the data is decompressed and stored in one or more databases 126 for immediate or later processing.

The analytics server 124 (e.g., the analytics processor server 310) may process the decompressed data and generate analytics in operation 709. The data may be processed immediately as it is received and stored or may be processed periodically (e.g., every few seconds, every few minutes, every hour, etc.). For example, the analytics server 124 may generate charts, graphs, heat maps, etc. from the stored data.

In operation 711, the analytics server 124 stores the processed data and generates analytics in one or more databases 126. The analytics are then ready to be provided to a user (e.g., developer, advertiser, etc.).

At operation 713, the analytics are provided to a user by the analytics server 124. For example, a user may access a user interface via a web browser or application to see a “dashboard” with analytics associated with one or more of the applications that he has created and is monitoring. A user may need to logon to the website or application before gaining access to the analytics.

A dashboard may have a number of features. For example, the dashboard may include application usage information (e.g., cohort analysis). This information may include a chart where users (e.g., developers) may add their own filters of data. These filters may include a data picker to choose a particular date or date range for the information, installs, active users (e.g., daily, weekly, monthly), sessions (e.g., number, duration, interruption (e.g., headset removed)), application version, custom events, location (e.g., country, city), client device (computer type (e.g., laptop, desktop, phone), brand, etc.), HMD (e.g., brand, model), GPU (e.g., brand, model, (GRAM, power (e.g., Oculus ready or not)), CPU (e.g., model, number of cores, brand (e.g., top 10), quad-core or not, Oculus ready or not), OS (e.g., type, version), peripherals (e.g., Leap Motion, Touch, Xbox controller, etc.), and sound (e.g., volume percent, on/off). The application usage information may also include a chart where parameters are overlaid on top of each other (e.g., to compare) and may include a retention chart. The application usage information may also include a chum table.

The application usage information may be in real-time/substantially real-time. For example, the application usage information may be live (e.g., total stats, list of event) or within the last predetermined period of time (e.g., 24 hours). The application usage information may also include user information such as a pie chart showing the most stereotypical information for users (e.g., “65% use Oculus Rift on average for 10 minutes”), and users' cohort analysis (e.g., gender, location, hardware, usage type, excitation level, etc.

The application usage information may also include performance information. For example, a performance tracker may show, for example, FPS over session length (average) with a segment for each HMD+GPU combination, a number of peaks under value for a duration (e.g., segment with HMD, GPU, OS), etc.

The performance information may also include a presence tracker. Presence is when the FPS are over a predetermined amount (e.g., 60) to ensure a good user experience. If the FPS drops too low (e.g., 40 FPS or under) for one second or more, this may be flagged as a “broken presence” unit (e.g., bad user experience). Presence may also refer to latency, such as, for example, a delay between a movement by the user and a reaction to the movement by the application. The presence data may be helpful for the developers to see how their application is doing (e.g., determine app performance). The presence tracker may include, for example, a bell curve for all headsets with a dropdown menu to view a bell curve for each device, a number of times the presence has been broken (e.g., less than 60 FPS for over one second), the number of time the presence has been broken per device used, a histogram with elapsed time with broken presence and time before people quit (which may include logs), latency (e.g., motion to pixel) with a color range (e.g., green, yellow, red), etc.

The performance information may further include error tracking (e.g., downloading raw log files), information on why the application is slowing down, and application benchmarks (e.g., overall, per HMD, etc.).

The application usage information may also include behavior information. For example, the information may include an excitement level (e.g., 1-5), on demand screenshots, and insights. Some example insights may be that the average user's GPU is rendering 50 FPS and so this needs to be fixed, users are leaving after 18 minutes of using the application (e.g., inflexion point), the app performance is low using a particular HMD, the app regularly crashes after a predetermined number of events, and so on.

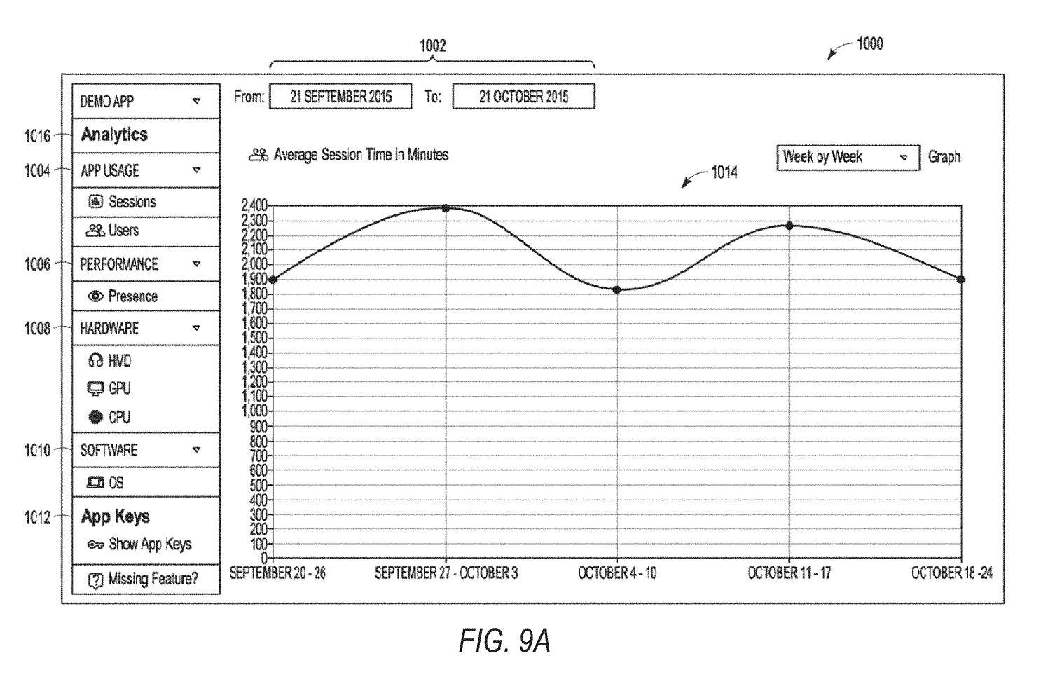

FIG. 9A shows an example user interface of a dashboard 1000. A user may have the option to choose a time frame 1002 for which to view analytics. The dashboard 1000 may have a menu 1016 that allows a user to choose to view analytics for a variety of parameters. In the example dashboard 1000 shown in FIG. 9A, the user can view analytics for application usage 1004 (e.g., sessions, users), performance 1006 (e.g., presence), hardware 1008 (e.g., HMD, GPU, CPU), and software 1010 (e.g., OS). The user can also view application keys 1012. The example dashboard 1000 shows a graph 1014 related to sessions for an average session time in minutes.

FIG. 9B shows an example dashboard 1020 displaying a graph 1022 of the number of sessions where FPS dropped under 60 for 5 seconds or more, and FIG. 9C shows an example dashboard 1030 displaying a graph 1032 that shows headset types. In another example, the analytics may be provided to the user by showing a video that runs a predetermined time (e.g., 5 seconds) that is a recording of users' positions at a certain point in time. In yet another example, the analytics may be provided to a user via a heat map, as described later below. Analytics information may be real-time or near real-time information.

In addition to the parameters tracked by the analytics plugin 144 as described above, the analytics plugin 144 may also be used to collect, compress and send data from the HMD, such as data associated with the position and/or orientation of the head of the user in the real world, the position and/or orientation of the virtual avatar in the virtual world, and depth information such as the distance of the virtual objects the user sees in the center of the HMD screen. An avatar is a virtual representation of a user in a virtual world. An avatar head is the virtual head of the avatar, corresponding to the point of view in real time of the user in the virtual world. This data may be used to provide further analytics and be presented to the user in the form of a heat map.

As explained above with respect to FIG. 6, an analytics plugin 144 (e.g., an analytics recorder plugin 212) may collect HMD data in operation 608, compress the data and send the data in operation 610 to one or more analytics server(s) 124, and may continue steps 608-612 until the user session ends.

In the data collection stage, raw sensor data, and optionally, world space avatar position and orientation, may be collected by the analytics recorder plugin 212 as shown in FIG. 2. World space avatar position is the position of the avatar in the virtual environment. This position is relative to the world origin. The world is the zero (0,0,0) position in the virtual world. As mentioned above, position data may not be available because some HMDs only have sensors to capture orientation data. In the case where position data is not present, the analytics recorder plugin 212 may only collect orientation data. The raw sensors position and/or orientation data may be collected by the analytics recorder plugin 212 directly at the HMD driver 204 layer.

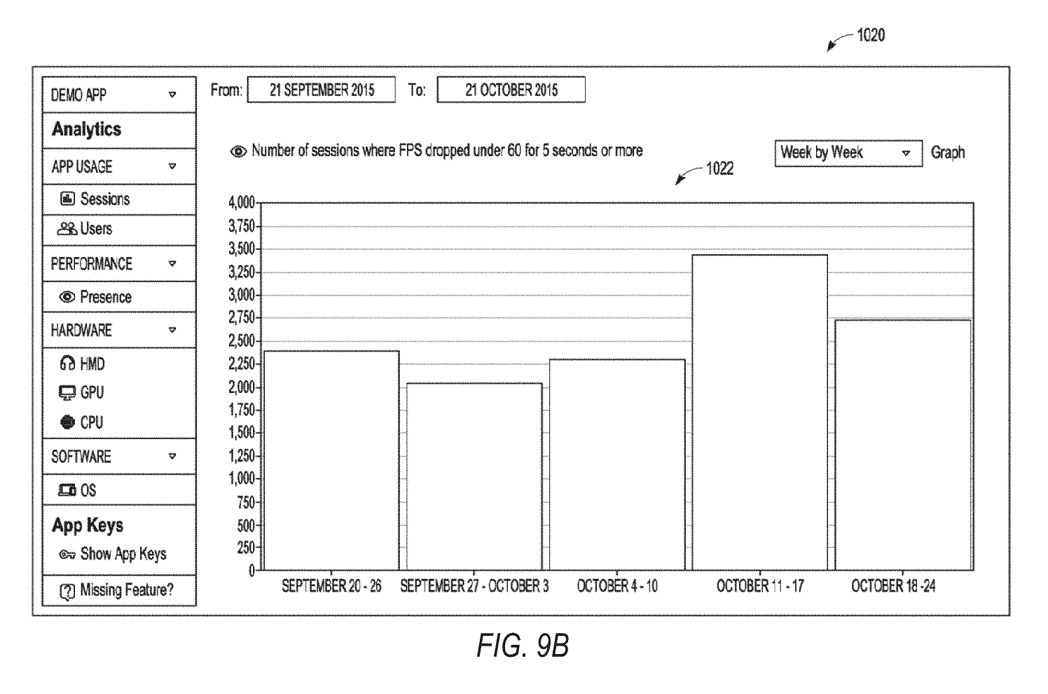

FIG. 10 shows physical world coordinates including a user HMD position/orientation (A) which is relative to a positional tracker (B) and a world origin (C). The world origin corresponds to the avatar body position/orientation in the virtual world. The positional tracker may be placed between the feet of the avatar in the virtual world.

In addition to this data, the analytics recorder plugin 212 may collect the avatar head position/orientation (e.g., relative to the avatar body position/orientation) and the avatar body position/orientation (e.g., relative to the virtual world scene origin). The analytics recorder plugin 212 may also collect the depth of a first object that intersects with a ray corresponding to the forward vector of the avatar head. For example, the analytics recorder plugin 212 may detect the collision of an object for a specified ray. The ray may have a position and an orientation. For example the position of the ray may be the center of the HMD or the center of the eyes of the avatar and the direction to a forward vector of the HMD or the direction forward of the head. The analytics recorder plugin 212 uses the ray to the collision function to determine the first 3D object (if any) and its distance from the origin of the ray, to determine the depth of the first object.

The data collected by the analytics recorder plugin 212 may be sampled to have a maximum resolution. In one example embodiment the analytics recorder plugin 212 may sample at twice the desired frequency according to the Nyquist theorem. For example, since the human muscular system cannot move faster than 6.5 Hz, the data collected by the analytics recorder plugin 212 may be sampled at 13 Hz (e.g., 6.5 Hz×2). Since 13 Hz is the maximum theoretical sampling rate, nothing is lost from the human movement capture.

The HMD sensors data may be pre-filtered by the device driver. For example, the data may be processed to remove noise from the sensor (e.g., the electromagnetic noise picked up by the sensor) by using an algorithm, such as a Kalman filter.

The data is accumulated by the analytics recorder plugin 212 into data blocks associated with a predetermined amount of time. For example, the data can be accumulated into a data block of five seconds. The data block is then compressed using a compression algorithm (e.g., to reduce the load on the network transmission) and sent to one or more analytic server(s) 124, as explained in detail above. Each data block may include some metadata (e.g., at the beginning of each data block) to, for example, identify a scene associated with the data block, identify the algorithm used to compress the data, etc. One or more analytics server(s) 124 may process the data to generate a statistical approximation of the data which can be interpreted as heat map data, as explained in further detail below. The computed data scene may then be sent to an analytics player plugin 404 to be interpreted and presented to a user (e.g., a developer).

There may be several data acquisition scenarios which may determine what data is available and what data is collected and sent to one or more analytics servers) 124. One example scenario may be where the virtual reality world is stationary (e.g., the user cannot move the avatar in the virtual world) and there is orientation tracking only. In this scenario, only the head orientation and the avatar orientation may need to be sent to the one or more analytics server(s) 124 because there may be no head translation in the virtual environment. An example of this scenario is a display of a 360 degree spherical video. The analytics server(s) 124 may assume in this scenario that the head position in the virtual world is at the origin (0,0,0). Accordingly, the data to be collected and sent in this scenario may include the physical world head orientation relative to the head position, and the virtual world avatar origin orientation. The virtual world avatar origin orientation may be the orientation of the avatar origin in the virtual world relative to the position of the avatar origin. For example, if the virtual avatar origin is rotated by 30 degrees to the right and the user is looking in the real world 20 degrees to the left, the resulting rotation will be 10 degrees to the right in the virtual world.

Another example scenario may be where the user can move the avatar in the virtual world and there is only orientation tracking available. In this scenario, the user can move the avatar in the virtual world, and so more information may be needed than the information in the scenario above. An example of this scenario may be a virtual reality mobile game which may not have a positional tracker. In this scenario, the analytics server(s) 124 may assume that the physical world origin and the virtual avatar origin correspond. Accordingly, the data to be collected and sent by the analytics recorder plugin 212 may include the physical world head orientation relative to the head orientation, the physical world head position (which may be fixed since this data is not available) relative to the world origin (e.g., approximated by the user height), the virtual world avatar origin orientation, the virtual world avatar origin position, and the depth of the first object in the forward direction of the head (e.g., for accurate heat map calculation). The virtual world avatar origin orientation may be the orientation of the avatar origin in the virtual world relative to the position of the avatar origin. The virtual world avatar origin position may be the position of the avatar origin in the virtual world relative to the virtual world origin.

Yet another example scenario may be where there is orientation and position tracking. In this scenario, the user can move the avatar in the virtual world and move his head in the physical world. The result may be a one-on-one immersive experience where the position and orientation of the user's head moves accordingly in the virtual world relative to the avatar origin orientation and position. Accordingly, the data to be collected and sent by the analytics recorder plugin 212 may include the physical world head orientation relative to the head position, the physical world head position, the virtual world avatar origin orientation, the virtual world avatar origin position, and the depth of the first object in the forward direction of the head. The physical world head position may be the position relative to the physical world origin. This value may be calculated from the HMD position relative to the tracker camera which is relative to the physical world origin. The virtual world avatar origin orientation may be the orientation of the avatar origin in the virtual world relative to the position of the avatar origin. The virtual world avatar origin position may be the position of the avatar origin in the virtual world relative to the virtual world origin.

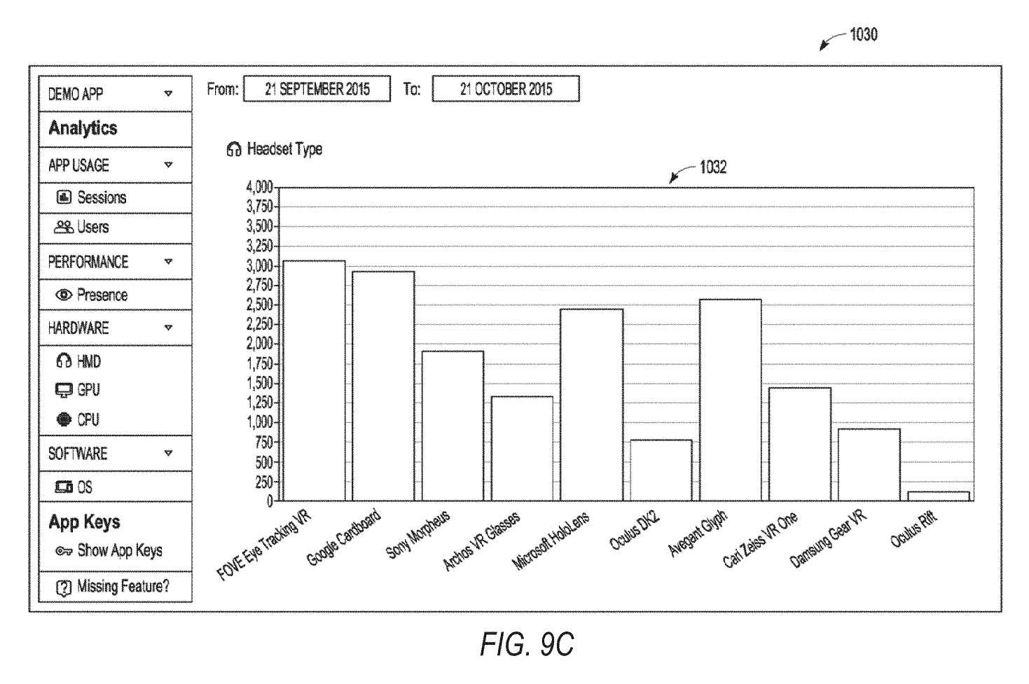

FIG. 11 is a flow chart illustrating aspects of method 1100 according to some example embodiments, for processing HMD data to generate analytics (e.g., for output in a heat map). For illustrative purposes, method 1100 is described with respect to the networked system 100 of FIG. 1. It is to be understood that method 1100 may be practiced with other system configurations in other embodiments.

At a specified time interval (e.g., every few seconds, every few minutes, every few hours, every few days, multiple times a day, etc.) an analytics server 124 (e.g., analytics processor server 310) may start a scheduled generation process which may call a heat map aggregation process to begin an aggregation phase. As shown in operation 1102, the analytics processor server 310 may read or retrieve new raw heat map data from one or more databases 126. The raw data may be received from a plurality of analytics player plugins 404 (e.g., from one or more client devices 110), as described above. The analytics processor server 310 may aggregate the raw data and add the aggregated data to any aggregated data that has already been aggregated, as shown in operation 1104. The aggregation process may put the raw data into a form that is easy for the analytics processor server 310 to process. For example, the raw data (e.g., a data structure containing the raw data) may be compressed using quantification or using a loss-less compression algorithm. This way, less data may be transmitted through the network. Also, new data is aggregated to the already aggregated data, and so data that has already been processed is not recalculated needlessly.

For example, there may be two types of heat maps for which the data needs to be aggregated and then processed to generate the heat maps. A first heat map may be a virtual world heat map (e.g., a positional heat map) and a second heat map may be a sight heat map. The data for the heat map(s) may be segmented into scene groups for each virtual reality application.

For the virtual world heat map, the analytics processor server 310 may aggregate each head position in the virtual world for a given time. Since the virtual world, or positional, heat map displays user position within the virtual application, orientation is not necessary for this calculation. The time may be sampled at a fixed interval in time at the beginning of a scene (e.g., the position of the head of the avatar in the virtual world would be recorded at a fixed interval in time). For example, if the sample is at 10 Hz, the first sample at recording may be the position of the virtual head (0, 1, 1) at the time sample 0 (e.g., 0 second since it is the beginning of the scene). The second sample at recording may be the position of the virtual head (0.1, 1.2, 1.1) at the time sample 1 (e.g., 0.1 second since the beginning of the scene). The third sample at recording may be the position of the virtual head (0.1, 1.3, 1.2) at the time sample 2 (e.g., 0.2 second since the beginning of the scene). For aggregation, the analytics processing server 310 may take all positions at a specified time sample for a scene and increment each data structure element corresponding to the position of each sample position.

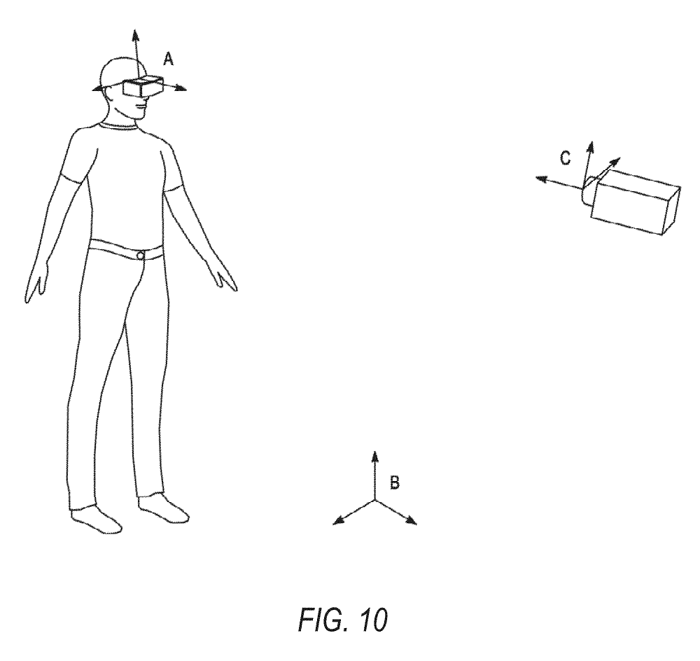

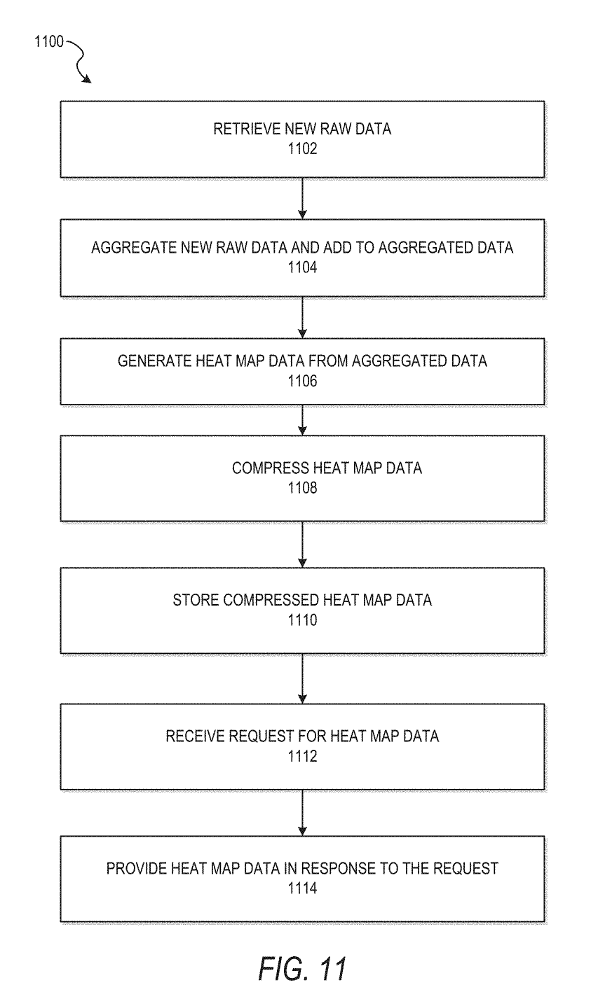

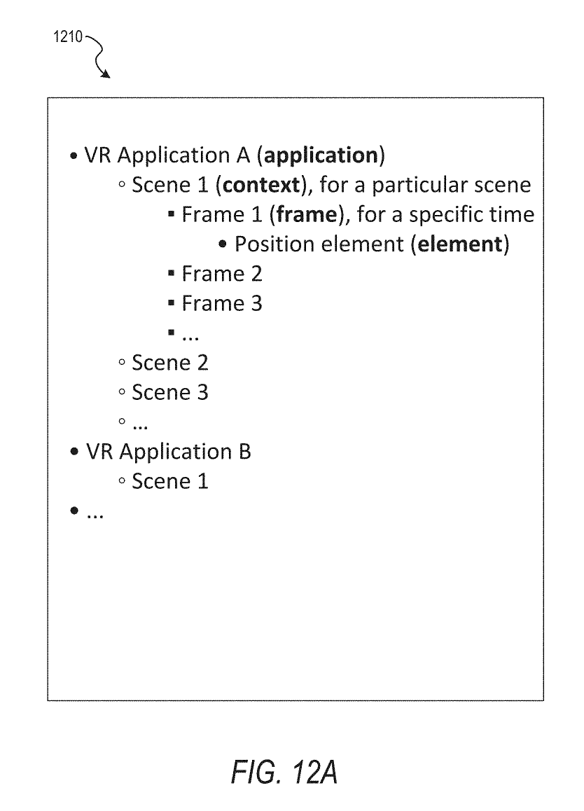

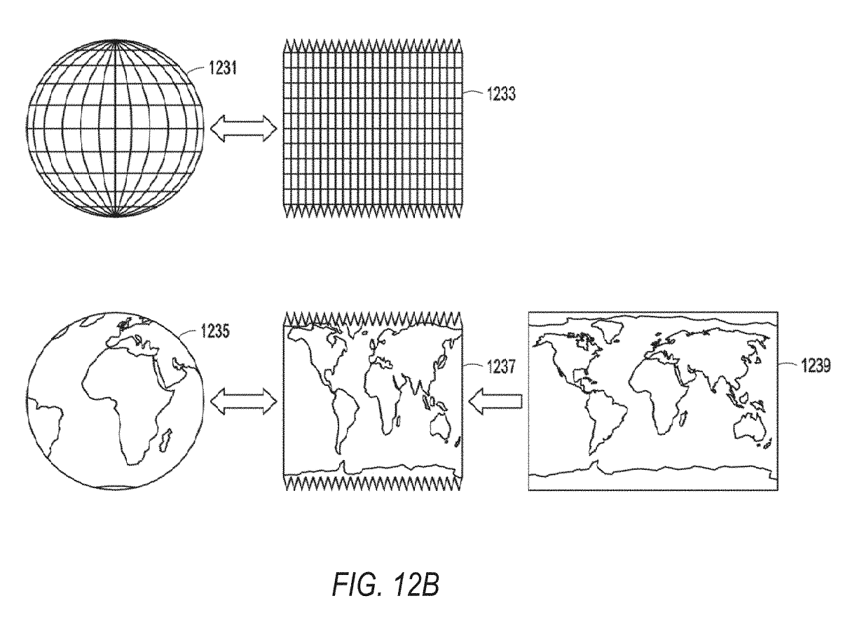

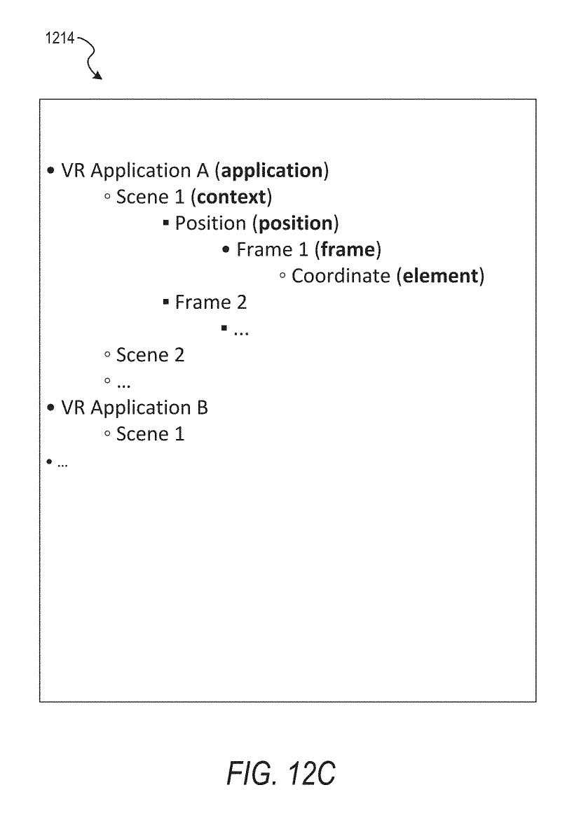

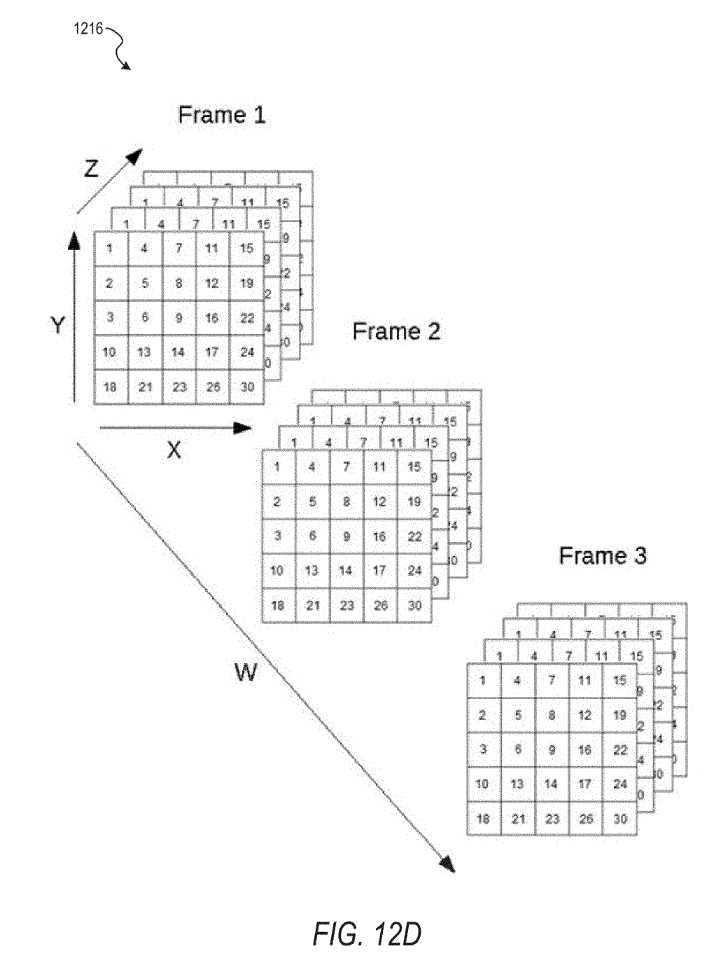

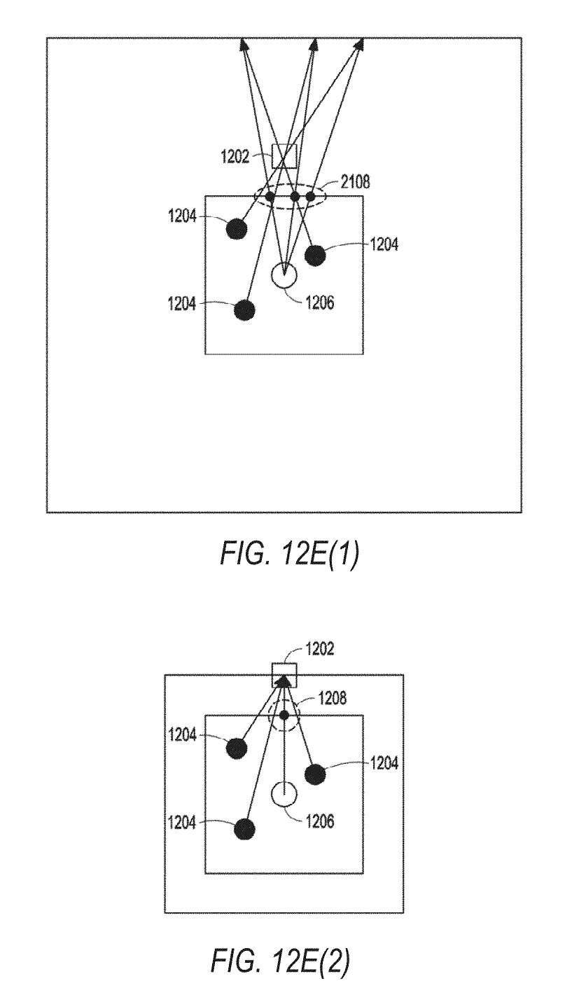

Accordingly, the analytics processor server 310 may create a hierarchical structure similar to the structure 1210 shown in FIG. 12A. For example, there may be one or more virtual reality (VR) applications (e.g., VR Application A, VR Application B, etc.). Each virtual reality application may comprise one or more scenes (e.g., Scene 1, Scene 2, Scene 3, etc.). Each scene may comprise one or more frames (e.g., Frame 1, Frame 2, Frame 3, etc.). And each frame may comprise one or more position elements. As shown in FIG. 12A, for example, a first virtual reality application may be VR Application A, comprising a plurality of scenes. Each of the plurality of scenes may comprise one or more frames. For example, Scene 1 may comprise Frames 1-3. And Frame 1 may comprise a position element. The position element may be a counter of the number of head position occurrences in the specified (x,y,z) small volume. In one example embodiment, a small volume may be one cubic meter.

For a sight heat map, the analytics processor server 310 may create a sphere around each center of non-null position elements of the virtual world heat map and create a temporal heat map of the sight for head orientation in the small volume for each frame. Each direction area, of a position area, of a given time, of a given scene for a virtual reality application is accumulated onto a matrix. FIG. 12B shows the direction from the center of the sphere is translated to a two dimensional (2D) matrix segmented into direction area. For example, a virtual sphere 1231 may be created around the volume element which is separated into small areas. These areas may correspond to a 2D UV matrix wrapped onto the sphere 1233. Each projected direction are accumulated to this matrix, creating an occurrence map for those areas (e.g., a heat map). Using a world map as an example in images 1235-1239, a spherical image is unwrapped to an equirectangular image. For example 1235 represents a spherical image. This type of image format is hard to manipulate, and so it may be unwrapped into a rectangular image 1237. The north pole corresponds to the top of the image 1237 and the south pole to the bottom of the image 1237. This may cause a deformation of the vertex as shown in image 1237. The gap in the bottom and the top of the image can be filled with a nearest neighbor algorithm to get a rectangular image 1239 that can be processed normally like any other image.

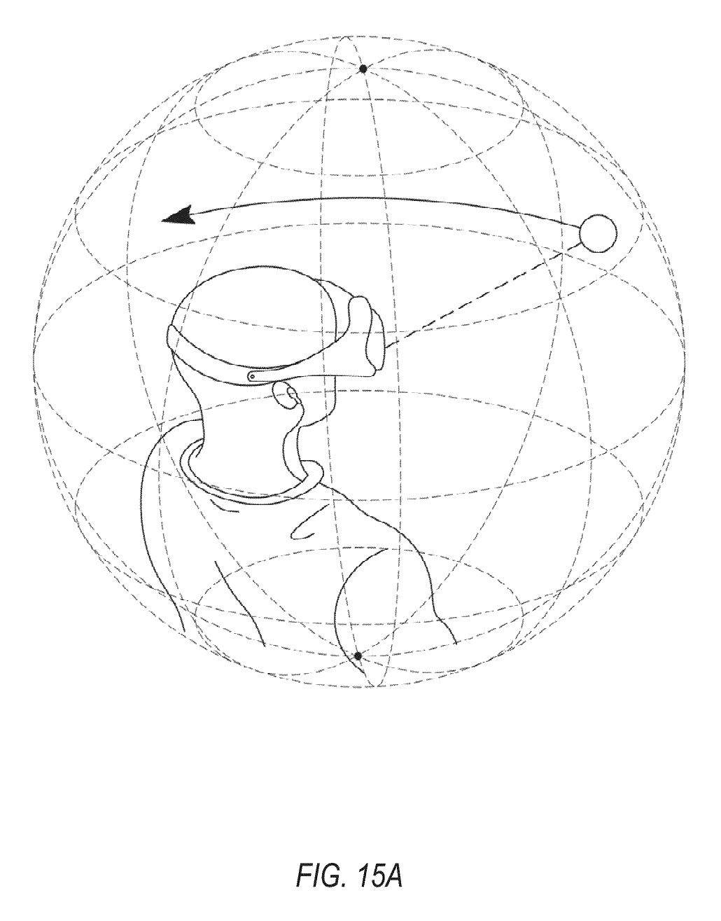

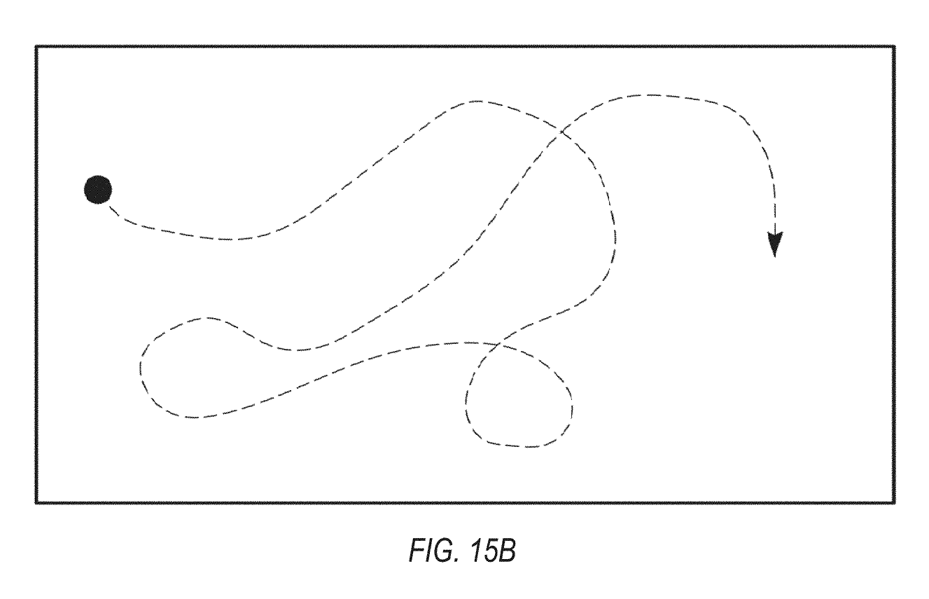

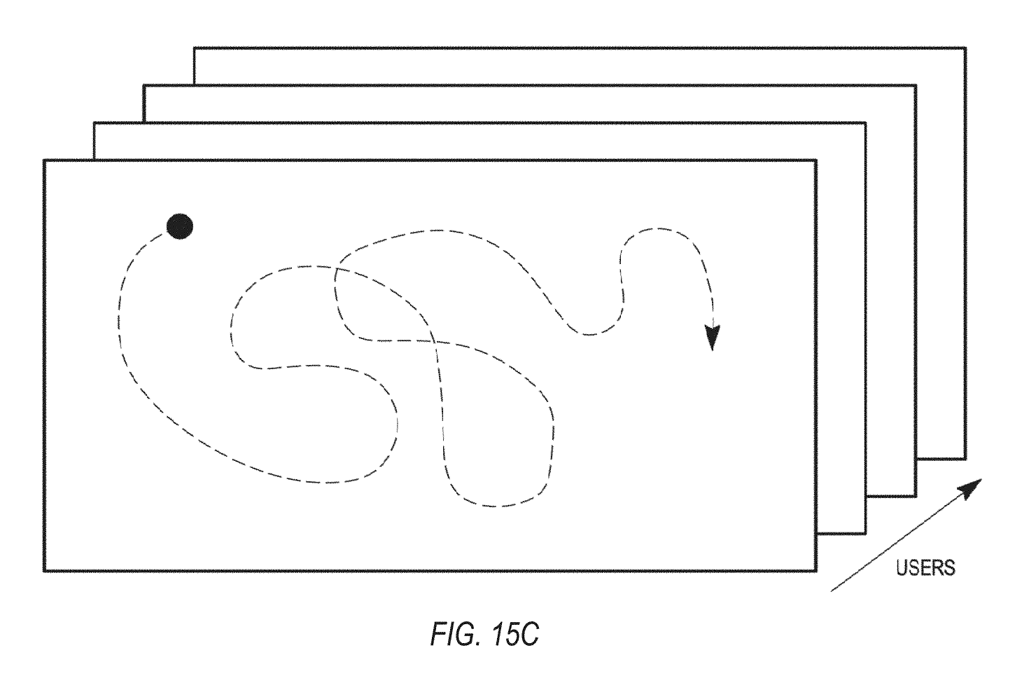

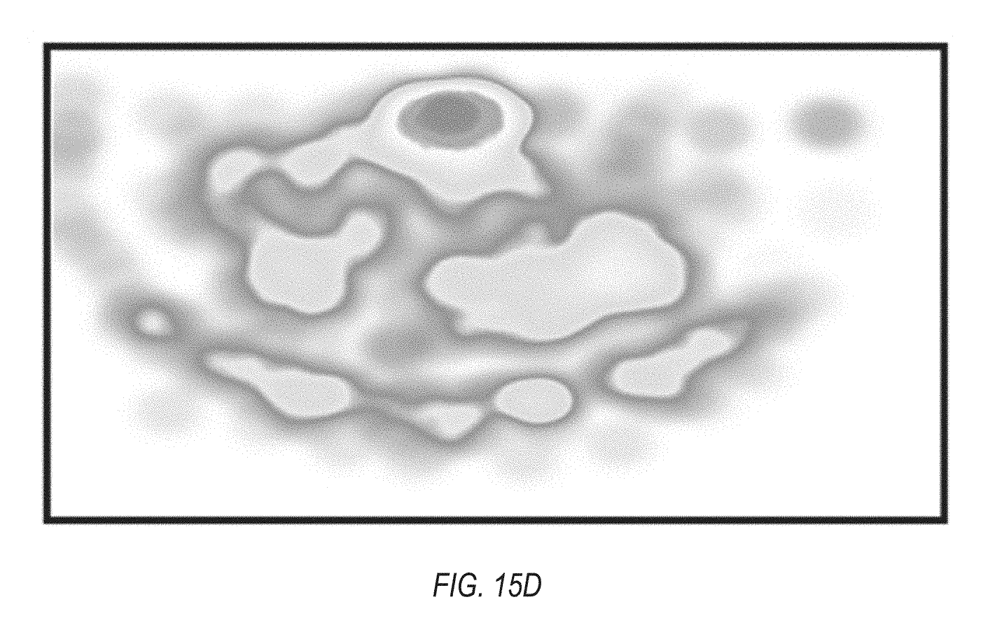

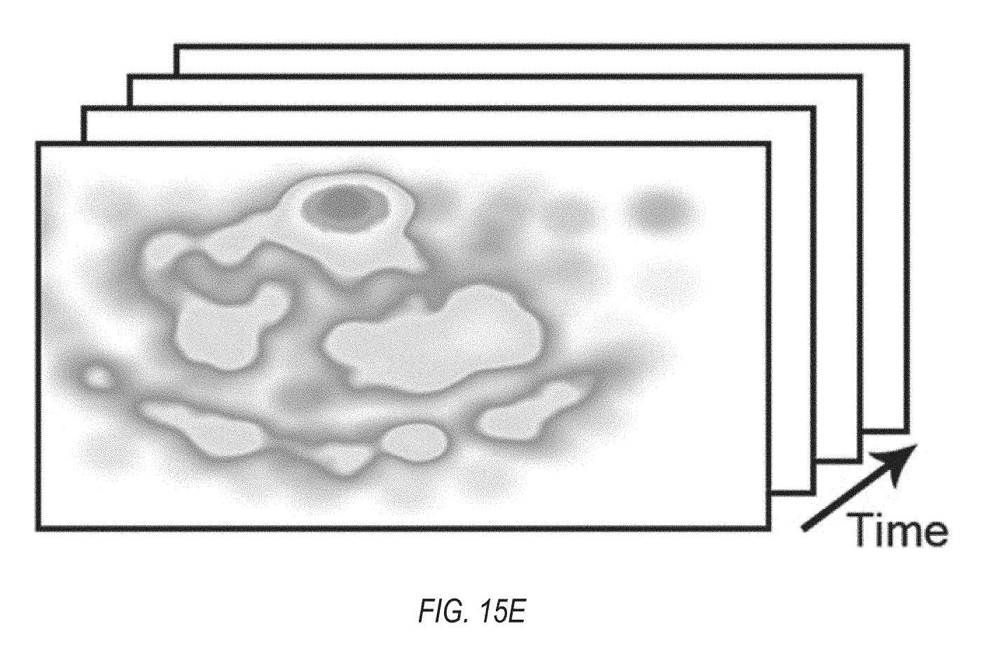

Another example is shown in FIGS. 15A-15E. FIG. 15A illustrates movement of the HMD and the virtual projection of the sight of the user to a point on a virtual sphere. FIG. 15B illustrates the movement of one user onto a frame. This representation contains all of the frames into one representation for one user. For example, frame zero is represented by the first black dot, frame one is represented by the second dot in the path, etc. In this representation the sphere from 15A has been unwrapped from a sphere matrix to a rectangular one. FIG. 15C shows an aggregation of each user's recording onto a single set of frames (e.g., a heat map). Each sight is represented by a dot. Each sight (e.g., each dot) of all frames zero are aggregated into one heat map frame zero. The same thing for all other frames (e.g., frame one, frame two, etc.). FIG. 15D is a visual representation of the heat map with colors. The image in FIG. 15D represents one frame in time. FIG. 15E illustrates a stack of all heat map frames representing a heat map video.

The analytics processor server 310 may create a hierarchical representation 1214 (similar to the virtual world heat map) in a database similar to the one shown in FIG. 12C. For example, VR Application A in FIG. 12C may comprise a Scene 1 (for a particular scene) which comprises a position for a particular position in the scene. The position may comprise a Frame 1 for a specific time. The Frame 1 may comprise a coordinate, which is an occurrence of a direction for a small surface intercepted by the direction ray onto a sphere centered at the center of the volume element.

Returning to FIG. 11, as shown in operation 1106, the analytics processor server 310 may generate heat map data from the aggregated data. The analytics processor server 310 may take the aggregated data and transform it into a compact format for each scene of each virtual reality application. For example, for generating a heat map of the position of the users, the analytics processor server 310 may need the position of the head of each user, relative to the world. The analytics processor server 310 may accumulate each head position (e.g., of a plurality of head positions) in a segmented four dimensional matrix. The first three dimensions (e.g., x, y, z) correspond to a position in the virtual world, and the fourth dimension is the time at that position (e.g., w). Each element of the matrix represents the accumulation of the users' head positions in the virtual world which are in the volume corresponding to the element position. At each iteration, the data gathered for a specific scene is computed at each time step and the value corresponding to the matrix element is incremented. For example, FIG. 12D shows example four dimensional matrices 1216. The first three dimensions of each matrix correspond to each possible element position (e.g., x, y, z). The fourth dimension correspond to each frame (e.g., dimension of time w).

For example, for a small scene (e.g., a small room for a fixed experience), the analytics processor server 310 may represent the multidimensional matrix using a multidimensional array. A benefit of this may be that basic operations on each element may be fast, but a large amount of memory may be needed unless the matrix contains a high ratio of unused (e.g., null) elements. A more precise heat map memory representation may be generated, which is limited by the size of the matrix, using an octree implemented with a linked list.

As explained above, two different heat maps may be used to present data to a user (e.g., developer). These include a virtual world heat map and a sight heat map. The virtual world heat map represents the position of the users in the scene of the virtual world at any time. Each user position at a certain time in the scene is accumulated into a multidimensional matrix element which may represent approximately one meter cubic.

A sight heat map may be generated at each small position element of the virtual world matrix. In one example embodiment, a small position element may be one cubic meter. The view of each user may be accumulated onto a cube map matrix. Depth information may be needed to have a better approximation of the direction. FIGS. 12E(1) and 12E(2) illustrate why an incorrect or fixed depth can map poorly to a projected screen. FIG. 12E(1) shows an incorrect depth projection. The arrows from the users' positions 1204 show each user's sight direction (e.g., the direction they are looking or viewing). All of the users sight the element area 1202. But, since the mapping screen is at an incorrect depth, the re-projected view of each element 1208 are incorrect. Accordingly, the point of view of the developer 1206 viewing the data will see three different directions (e.g., three distinct heats on the map). If the screen is at the same depth of the object, as shown in FIG. 12E(2), the direction of the users' position 1204 view may be precisely computed at the perspective of the developer 1206 view.

Returning to FIG. 11, at operation 1108 the generated heat map data is compressed and then at operation 1110 the compressed heat map data is stored in one or more databases 126. For storage and data transmission efficiency, the heat map data may be stored in a particular file format. For example, for the virtual world heat map data, each frame of the virtual world heat map may be encoded with an octree representation. FIG. 12F shows an octree representation of a positional heat map frame for a particular time where each circle is an occurrence number. This approach may help a heat map player plugin (e.g., analytics player plugin 404) to render fast approximation of the position heat map onto the virtual reality application editor scene. Also, this structure takes less data than a three dimensional (3D) matrix. So, for a given scene in a virtual reality application, a file may contain all data for all frames.

The sight heat map may be separated into different files. One file may contain all the frames of a particular area (e.g., from the non-null positions areas of the virtual world heat map). Each element of a frame may be a 2D matrix of all possible directions and each element contains the occurrence (e.g., number of views pointing in a particular direction area) for a particular time. FIG. 12G shows a matrix 1216 of a frame. Each element in the matrix 1216 is a number of occurrence for a direction area.

For each frame (e.g., each 2D matrix), the analytics processor server 310 may use a run length encoding (RLE) similar to one used in the entropy encoding after the zigzag in PEG. For example, 0003406700 becomes (3,3)(0,4)(1,6)(0,7)(0,0), in which (0,0) is EndOfBlock. In the example shown in FIG. 12G, the analytics processor server 310 may encode each column, from bottom to top, and from left to right. Using the matrix 1216 in FIG. 12G, this would result in the following encoded data (3,10)(2,30)(0,20)(1,50)(3,60)(0,40)(2,70)(2,80)(0,0).

Once the HMD data is processed into heat map data, it is available to be provided to a user (e.g., developer). For example, it may be provided to an analytics player plugin 404 in a virtual reality application editor 402. The analytics processor server 310 may receive a request for the processed heat map data, as shown in operation 1112, and then provide the heat map data to the requester (e.g., the analytics player plugin 404) in response to the request. The analytics player plugin 404 may provide a way to display and visualize the heat map data for a particular scene.

For example, the heat map data may be displayed as a virtual world heat map (e.g., positional heat map) or a sight heat map. A virtual world heat map may correspond to a position in time (relative to the beginning of the scene played) and the position in the virtual world of the avatars (e.g., where the most users are positioned at a specified time). A sight heat map may be a heat map of the sight (e.g., corresponding to the direction of the HMD) of particular positions in the virtual world (e.g., where the most users are looking or viewing at a specified time).

The virtual world or sight heat map may be represented by a volumetric transparent cloud-like colored heat map (e.g., using a colors palette such as a spectral color palette). At each position of the virtual world's matrix element, a sight heat map may be visualized. The developer may view a spherical representation (which may be a cube map) representing the accumulated users' sights at that particular position. Hot spots (e.g., where the most users are positioned or viewing at a specified time) may be visible by an opaque red. Gradually, the opacity and color of the spots may change for matrix elements which are colder (e.g., have fewer users). For example, the hottest area may be represented in red, then the color may change to orange, yellow, green, blue, purple, from most users to fewest users. Areas where there are no users at all may be transparent. The volumetric heat map may be superimposed on the virtual world assets of an application to indicate to the developer where the most users are positioned or viewing in the virtual world.

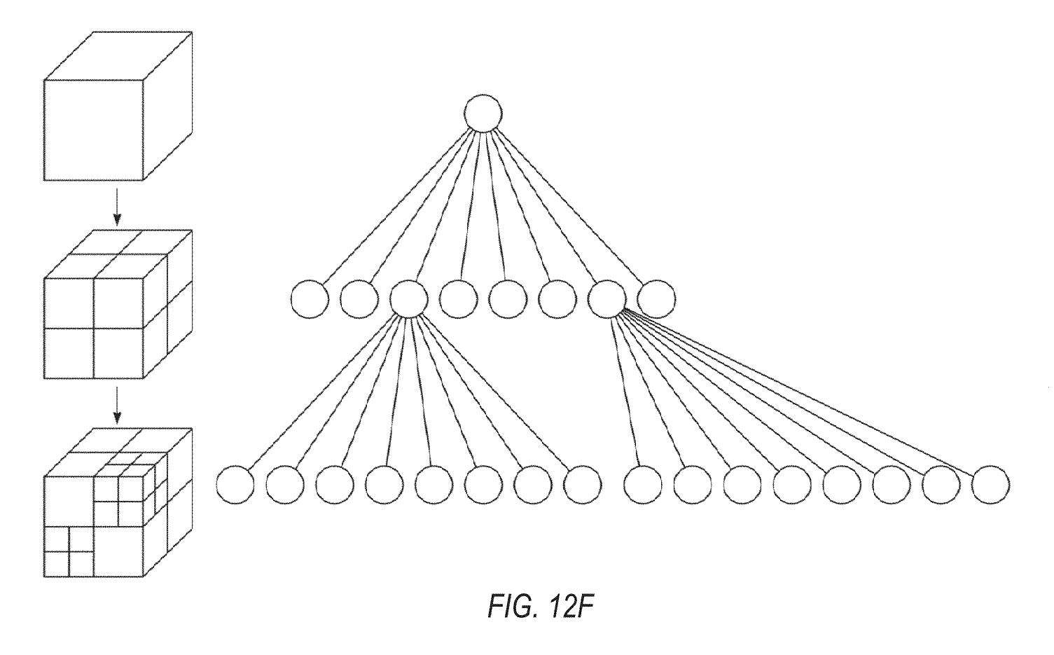

FIG. 13 is a flow chart illustrating aspects of a method 1300, according to some example embodiments, for converting heat map data into a heat map to be viewed by a user. For illustrative purposes, method 1300 is described with respect to the networked system 100 of FIG. 1. It is to be understood that method 1300 may be practiced with other system configurations in other embodiments.

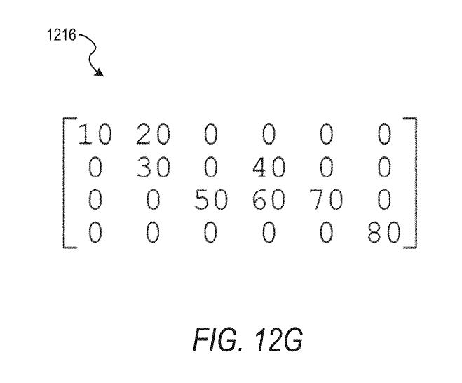

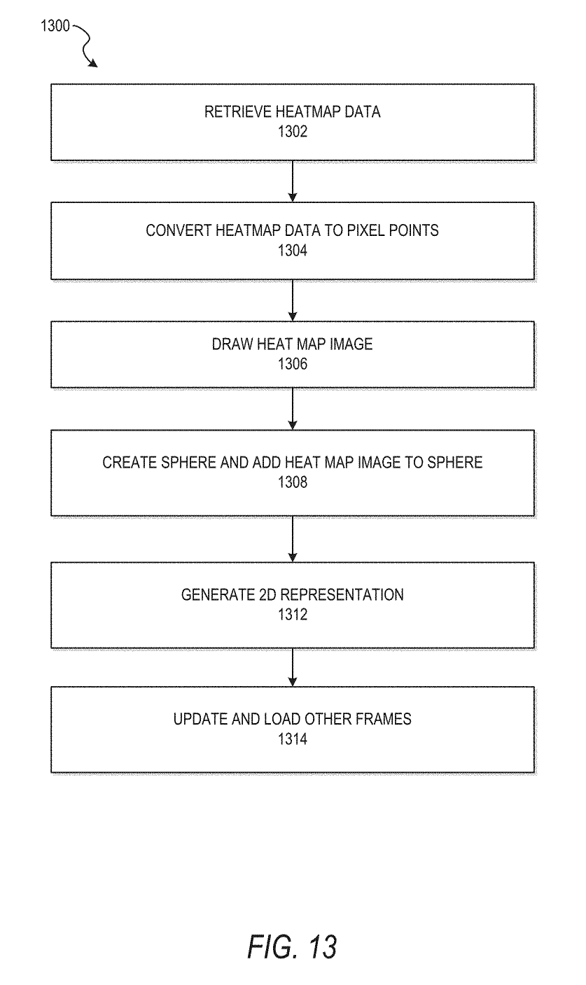

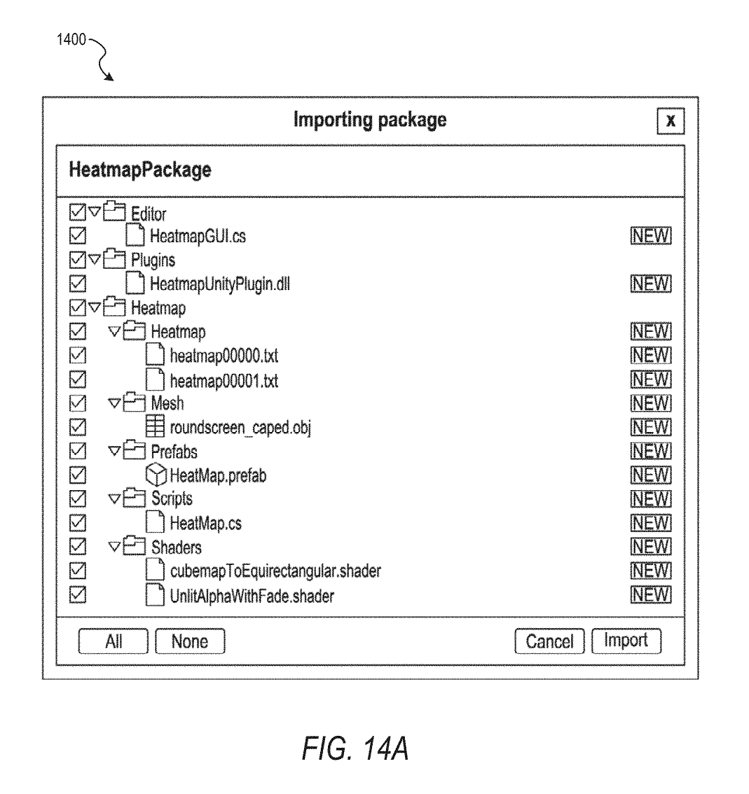

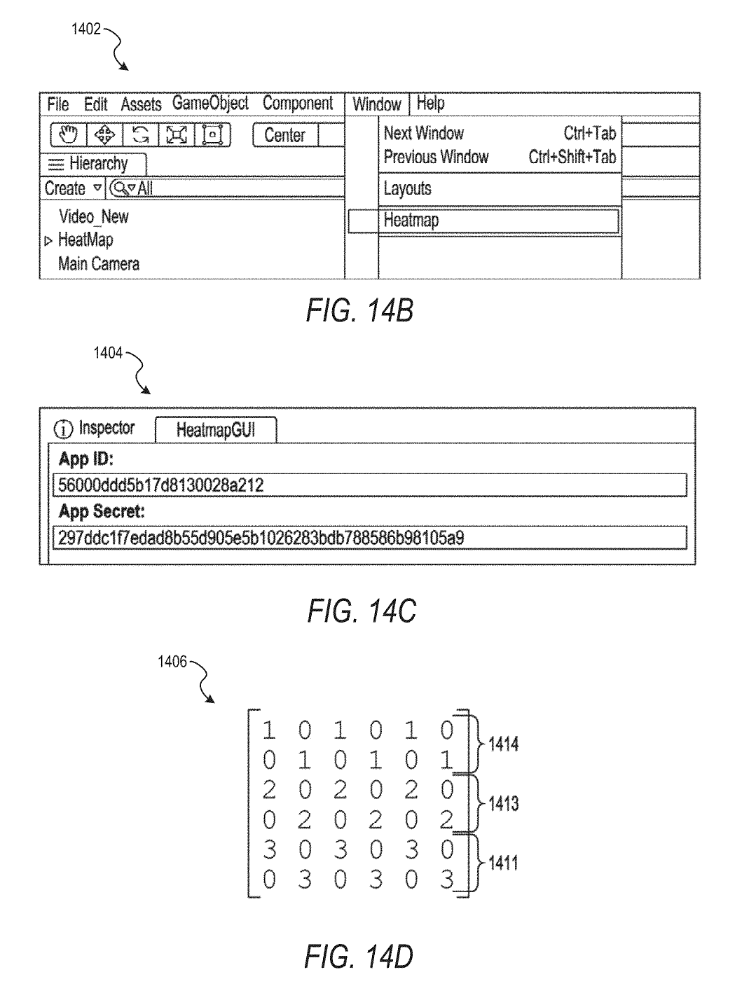

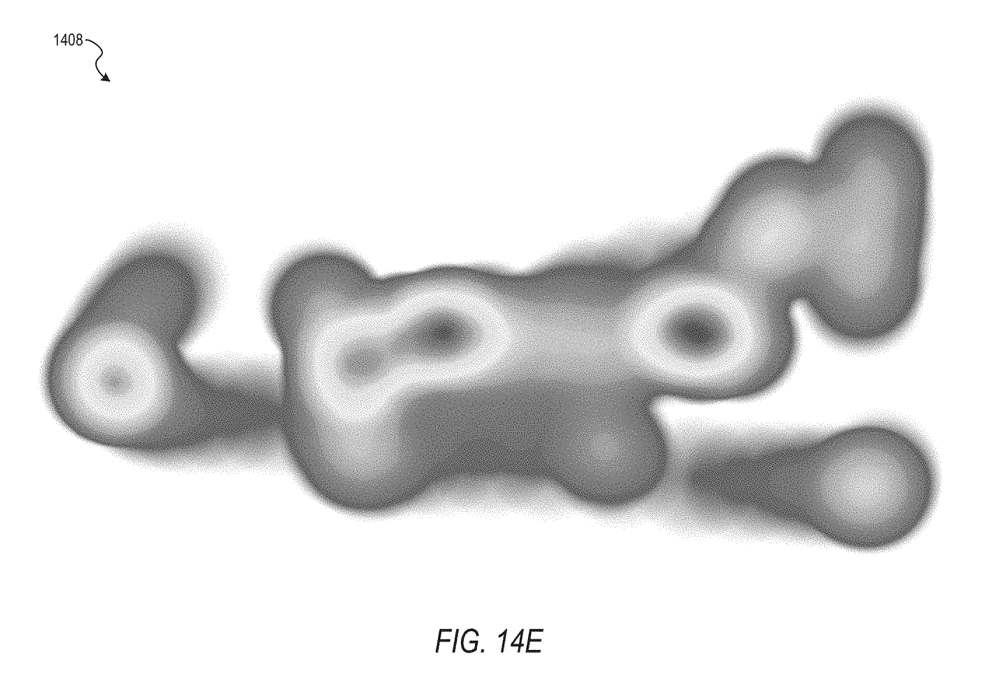

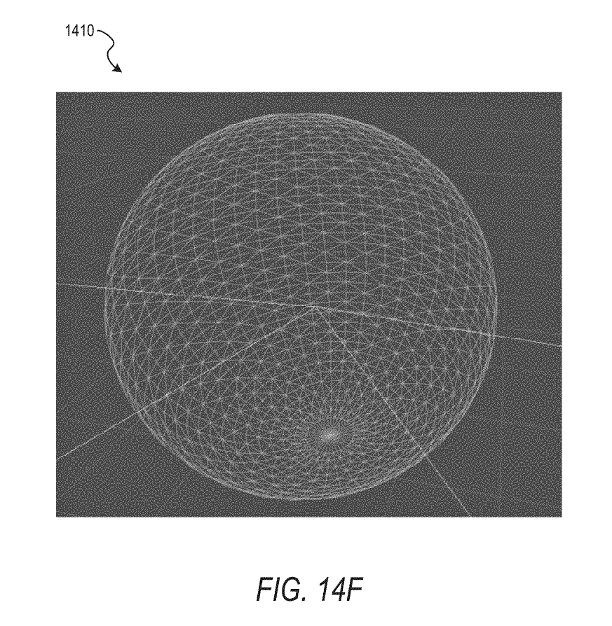

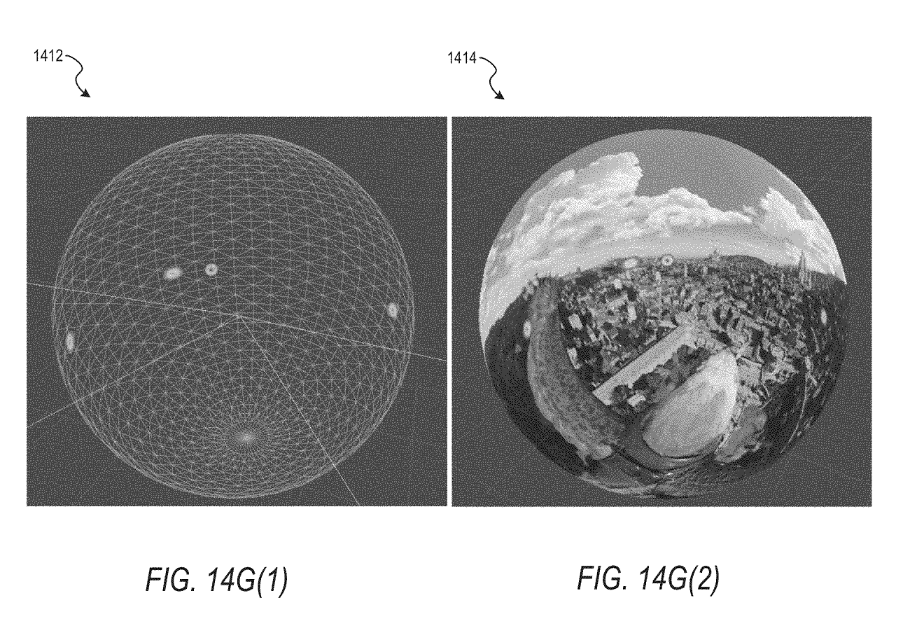

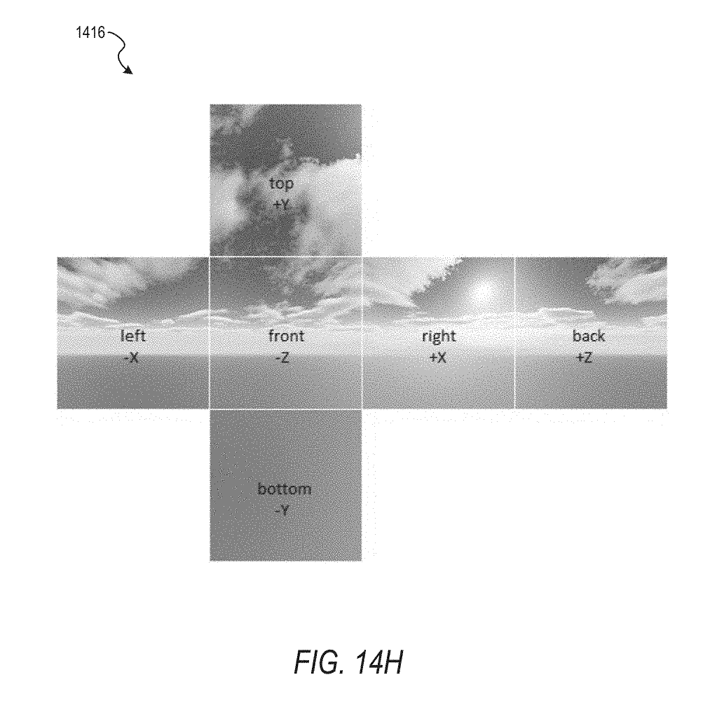

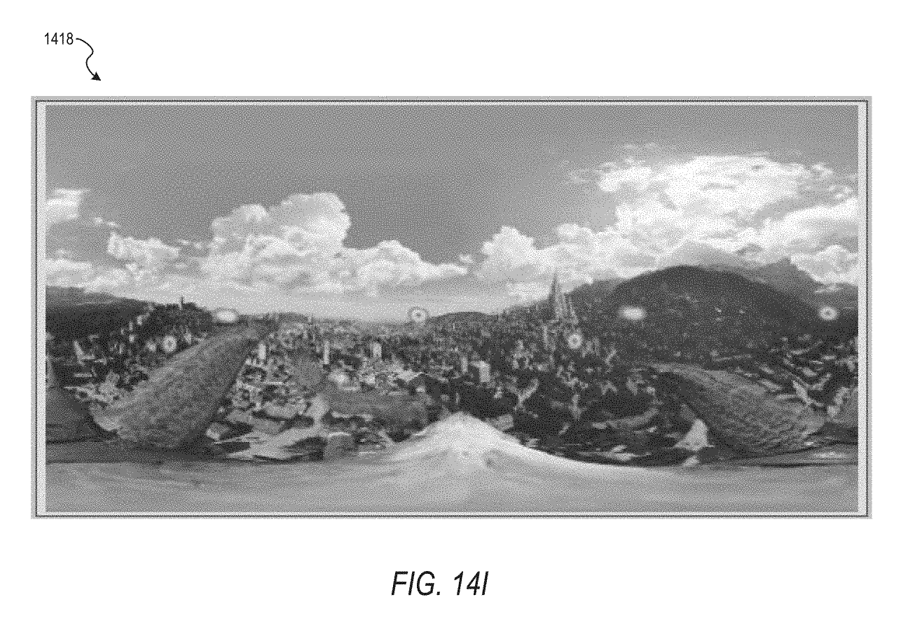

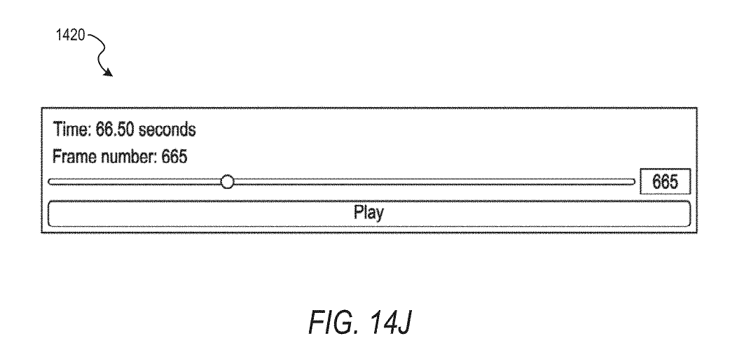

To view a heat map, a user (e.g., developer) may need to utilize a particular heat map player application (either a standalone application or an application via a web browser) or download a heat map player plugin (e.g., analytics player plugin 404) that may be used with an existing application. For example, a user may download a heat map player plugin from a website. An analytics server 124 may receive a request from a client device 110 or developer device 140 for the heat map player plugin, and provide the heat map player plugin to the client device 110 or the developer device 140 associated with the user. The heat map player plugin may be utilized as part of a development platform 142 such as a virtual reality application editor 402. For example, a user may be a developer that uses a virtual reality application editor 402 such as Unity. FIG. 14A shows a screen shot 1400 of how a user may view the heat map player plugin inside a Unity project. For example, the heat map player plugin may be a DLL for Unity. When the developer imports the plugin into Unity, assets may be added to the project. FIG. 14A shows an example list of assets that may be added to a project in Unity when importing the heat map player plugin into Unity. The developer may choose to import all of the assets, none of the assets, or a subset of the assets.

Once the heat map player plugin is imported into the virtual reality application editor 402, a new menu item may be available to access the heat map as shown in FIG. 14B.

After importing the heat map plugin, the developer may enter information about his application in an interface associated with the heat map player plugin. For example, the developer may enter an identifier (ID) of the application for which he wishes to view heat map data and the application key (or secret as shown in FIG. 14C. The heat map player plugin may verify the application ID and key. If the heat map player plugin cannot verify the application ID and key, it may notify the user that verification was not successful (e.g., display a message). If verification is successful, the heat map player plugin may take data associated with a current scene name in an opened project in the virtual reality application editor 402. For example, a scene may represent a level of a game, a different 3D environment, or a subset of a scene such as a particular item or event within a scene (e.g., a particular building, room in a building, an item in the scene touched by a user, etc.). The heat map player plugin may view a scene as a sub-project since it is one scene (or subset of a scene) within a project that may comprise other scenes (or subsets of scenes).

As shown in operation 1302 of FIG. 13, the heat map player plugin may retrieve heat map data. As explained earlier with respect to FIG. 4 and the analytics player plugin 404, the heat map player plugin may request and receive compressed heat map data, decompress the heat map data, and then process the heat map data and present it to a user. In one example, the compressed heat map data may be a compressed Gzip file that may contain all the information for the recorded heat map of the entire scene (or subset of the scene), in bytes. Since these bytes represent nothing without a knowledge of their representations, this can act as security to protect the heat map data. The compressed file may be stored directly in virtual memory instead of physically on the hard drive. The heat map player plugin may read the file and extract the data to get the bytes.

Once the heat map data is loaded into memory, the heat map player plugin may convert the data to pixel points, as shown in operation 1304. For example, the heat map player plugin may first read the first byte to identify a version of the heat map data. This may be useful to adapt the heat map player plugin to a newer version and add backward compatibility.

The heat map player plugin may determine the next bytes to read based on the resolution of the heat map. The heat map player plugin may need to read the same amount of pixels as the number of pixels for the heat map. For example, each frame of the heat map represents a number of bytes calculated using width multiplied by height bytes. Each of the bytes or pixels may have an integer value representing the number of users who have looked at the pixel while recording the orientation of their head. The integer value is the number of times that pixel has been “seen” by users. FIG. 14D shows an example frame 1406 of 6×6=36 pixels. As can be seen from this example, the bottom of the image 1411 is looked at more often by users than the middle 1413 or top 1414 of the image.

At operation 1306, the heat map player plugin may draw the heat map image for each frame based on the pixels tagged as “seen” by users. For example, from the matrix of each frame that identifies which pixel has been seen by users, the heat map player plugin may draw a heat map based on the value of each pixel. A higher value may mean that more users looked at the same position for a specified time. A hot color (e.g., orange or red) may be used to represent pixels with higher values. A lower value may mean that less users have looked at the same position for a specified time. A cold color (e.g., blue) may be used to represent pixels with lower values. The color may be adjusted with a normalization to be sure that the highest spot is red and the lowest spot is blue. Where there is no color, it may mean that no users have looked at that pixel or that a very low amount of users have looked at that pixel. FIG. 14E shows an example heat map 1408 generated from a matrix of pixels.

At operation 1308 the heat map player plugin may create a sphere and add the heat map image to the sphere. For example, to generate a heat map in virtual reality, it may be necessary to put the heat map image in a sphere where the user/developer will be put inside to see the heat map in each direction. To do this, the heat map player plugin will automatically create a sphere in the scene, as shown in FIG. 14F, and then add the heat map image to the intern faces of the sphere as shown in FIGS. 14G(1) and 14G(2).

The heat map player plugin may then get a cube map of a camera inside the sphere and display an equirectangular image. Once the heat map is generated in the sphere, the heat map player plugin may use a cube map technique to generate a 21) representation of all possible directions of the heat map, as shown in operation 1312. The cube map technique may take six images from each direction and merge them in a way to obtain a rectangular image with distortion in the poles as shown in FIG. 11.4H. The final result may be an equirectangular image 1418 as shown in FIG. 14I.

As shown in operation 1314, the heat map player plugin may update and load other frames based on a position and frame selector. Now that a heat map may be shown for a selected frame, and since all of the heat map is saved in memory, the developer may use a tool to change the frame to be a show, or to play an animation of the heat map by displaying multiple frames over time. An example interface 1420 for a developer to use to change the current frame shown in both the sphere and equirectangular images is shown in FIG. 14J.

In addition to the parameters discussed above that may be captured and sent by the analytics recorder plugin 212, the same or other data may be captured to be used for advertising analytics. For example, based on the data of where a user is viewing and how long, the analytics server 124 may determine what ads users are viewing, how long the users are viewing the ad(s), and what the user behavior was when viewing the ad(s). An ad may include a 360 degree ad, an ad on a surface (e.g., wall) of a virtual reality environment, a video banner, etc. This data may also be used to determine ad placement within a virtual reality application 202. For example, an ad may be placed in a location that most users typically view. In the alternative, an ad may be placed in a location that most users typically do not view, so that users are not distracted from the game.

The analytics server 124 may provide one or more ads to be included in a virtual reality application. For example, a developer may include a “tracker” inside the virtual reality application that indicates a specific location in the application where the developer wants the ad to be displayed to a user. The analytics plugin in the virtual reality application may use the tracker to determine where to display the ad in the application. In the alternative, the analytics plugin may automatically determine the best location to place the ad based on user data, etc., as explained above.

The analytics plugin may send a request to the analytics server 124 (e.g., via API server 120) to request an advertisement. The analytics server 124 may return an appropriate ad based on analytics for the application, data on the user, etc. to the analytics plugin. For example, the analytics server 124 may determine location information (e.g., based on IP address, GPS data of the client device 110, etc.), user behavior, user name, user profile, user social profile, etc., and use one or more of this information to determine an appropriate ad. The analytics plugin can then cause the ad to display in the appropriate location in the virtual reality application. The analytics server 124 may access ad content from one or more databases 126 or from ad content provider(s) 150. The ad may be streamed directly from the analytics server 124. Revenue sharing may be determined based on the type and placement of ads, etc.

The analytics plugin 144 in the virtual reality application 202 may also include a custom video player that plays video in 360 degrees. For example, an ad may be streamed directly from the analytics server 124 to display the ad real-time to the user. A 360-degree ad allows the user to look around in the ad, etc.

An ad displayed in the virtual reality application 202 may be an actionable ad. An actionable ad allows a user to activate certain features or perform certain actions by looking at the ad or at a “button” in the ad. For example, if a user looks at an ad and holds his gaze for a predetermined period of time (e.g., one second), further detail may be displayed associated with the ad.

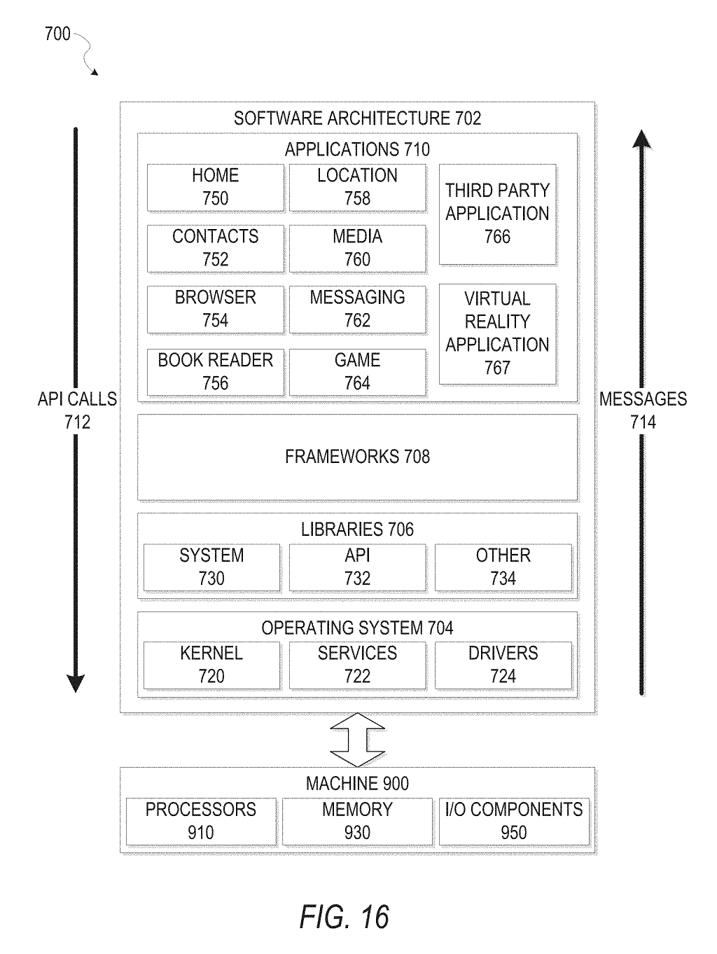

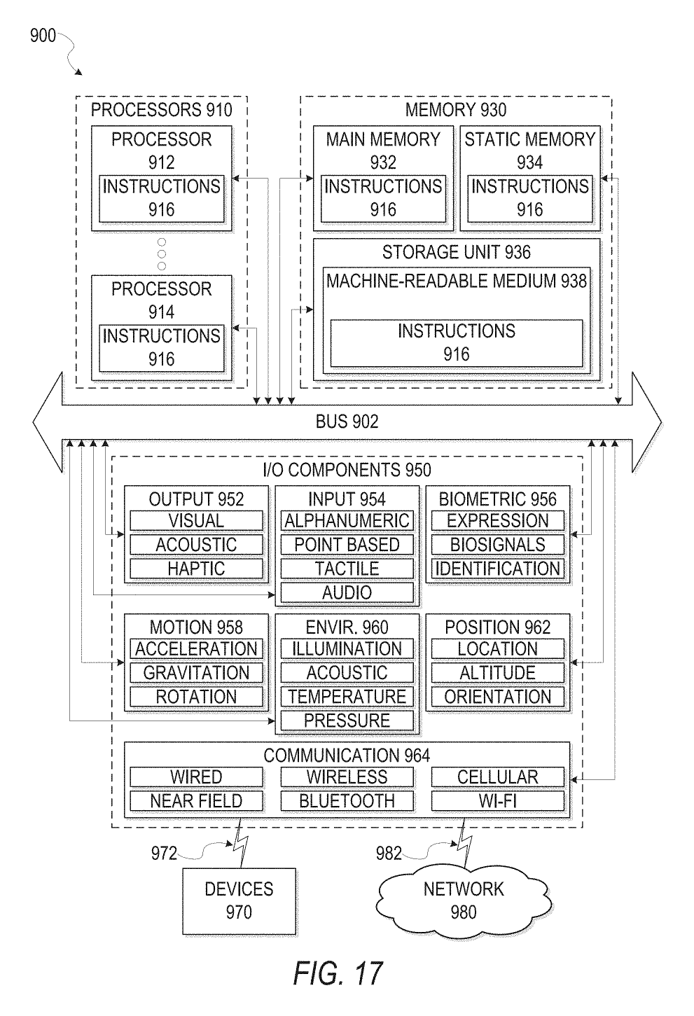

FIG. 16 is a block diagram 700 illustrating an architecture of software 702, which can be installed on any one or more of the devices described above. For example, in various embodiments, client devices 110, developer device(s) 140, and server system 102, API server 120, web server 122, analytics server(s) 124, and third party server(s) 130 may be implemented using some or all of the elements of software architecture 702. FIG. 16 is merely a non-limiting example of a software architecture, and it will be appreciated that many other architectures can be implemented to facilitate the functionality described herein. In various embodiments, the software architecture 702 is implemented by hardware such as machine 900 of FIG. 17 that includes processors 910, memory 930, and I/O components 950. In this example, the software architecture 702 can be conceptualized as a stack of layers where each layer may provide a particular functionality. For example, the software architecture 702 includes layers such as an operating system 704, libraries 706, frameworks 708, and applications 710. Operationally, the applications 710 invoke application programming interface (API) calls 712 through the software stack and receive messages 714 in response to the API calls 712, consistent with some embodiments.

In various implementations, the operating system 704 manages hardware resources and provides common services. The operating system 704 includes, for example, a kernel 720, services 722, and drivers 724. The kernel 720 acts as an abstraction layer between the hardware and the other software layers, consistent with some embodiments. For example, the kernel 720 provides memory management, processor management (e.g., scheduling), component management, networking, and security settings, among other functionality. The services 722 can provide other common services for the other software layers. The drivers 724 are responsible for controlling or interfacing with the underlying hardware, according to some embodiments. For instance, the drivers 724 can include display drivers, camera drivers, BLUETOOTH® or BLUETOOTH® Low Energy drivers, flash memory drivers, serial communication drivers (e.g., Universal Serial Bus (USB) drivers), WI-FI® drivers, audio drivers, power management drivers, and so forth.

In some embodiments, the libraries 706 provide a low-level common infrastructure utilized by the applications 710. The libraries 706 can include system libraries 730 (e.g., C standard library) that can provide functions such as memory allocation functions, string manipulation functions, mathematic functions, and the like. In addition, the libraries 706 can include API libraries 732 such as media libraries (e.g., libraries to support presentation and manipulation of various media formats such as Moving Picture Experts Group-4 (MPEG4), Advanced Video Coding (H.264 or AVC), Moving Picture Experts Group Layer-3 (MP3), Advanced Audio Coding (AAC), Adaptive Multi-Rate (AMR) audio codec, Joint Photographic Experts Group (JPEG or JPG), or Portable Network Graphics (PNG)), graphics libraries (e.g., an OpenGL framework used to render in two dimensions (2D) and three dimensions (3D) in graphic content on a display), database libraries (e.g., SQLite to provide various relational database functions), web libraries (e.g., Web pit to provide web browsing functionality), and the like. The libraries 706 can also include a wide variety of other libraries 734 to provide many other APIs to the applications 710.

The frameworks 708 provide a high-level common infrastructure that can be utilized by the applications 710, according to some embodiments. For example, the frameworks 708 provide various graphic user interface (GUI) functions, high-level resource management, high-level location services, and so forth. The frameworks 708 can provide a broad spectrum of other APIs that can be utilized by the applications 710, some of which may be specific to a particular operating system 704 or platform.

In an example embodiment, the applications 710 include a home application 750, a contacts application 752, a browser application 754, a book reader application 756, a location application 758, a media application 760, a messaging application 762, a game application 764, virtual reality application 767, and a broad assortment of other applications such as a third party applications 766. According to some embodiments, the applications 710 are programs that execute functions defined in the programs. Various programming languages can be employed to create one or more of the applications 710, structured in a variety of manners, such as object-oriented programming languages (e.g., Objective-C, Java, or C++) or procedural programming languages (e.g., C or assembly language). In a specific example, the third party application 766 (e.g., an application developed using the ANDROID™ or IOS™ software development kit (SDK) by an entity other than the vendor of the particular platform) may be mobile software running on a mobile operating system such as IOS™, ANDROID™, WINDOWS® Phone, or another mobile operating system. In this example, the third party application 766 can invoke the API calls 712 provided by the operating system 704 to facilitate functionality described herein.

FIG. 17 is a block diagram illustrating components of a machine 900, according to some embodiments, able to read instructions from a machine-readable medium (e.g., a machine-readable storage medium) and perform any one or more of the methodologies discussed herein. Specifically, FIG. 17 shows a diagrammatic representation of the machine 900 in the example form of a computer system, within which instructions 916 (e.g., software, a program, an application 710, an applet, an app, or other executable code) for causing the machine 900 to perform any one or more of the methodologies discussed herein can be executed. In alternative embodiments, the machine 900 operates as a standalone device or can be coupled (e.g., networked) to other machines. In a networked deployment, the machine 900 may operate in the capacity of a server machine (e.g., server system 102, API server 120, web server 122, analytics server(s) 124, third party server 130, etc. or a client device 110 or developer device(s) 140 in a server-client network environment, or as a peer machine in a peer-to-peer (or distributed) network environment. The machine 900 can comprise, but not be limited to, a server computer, a client computer, a personal computer (PC), a tablet computer, a laptop computer, a netbook, a personal digital assistant (PDA), an entertainment media system, a cellular telephone, a smart phone, a mobile device, a wearable device (e.g., a smart watch), a smart home device (e.g., a smart appliance), other smart devices, a web appliance, a network router, a network switch, a network bridge, or any machine capable of executing the instructions 916, sequentially or otherwise, that specify actions to be taken by the machine 900. Further, while only a single machine 900 is illustrated, the term “machine” shall also be taken to include a collection of machines 900 that individually or jointly execute the instructions 916 to perform any one or more of the methodologies discussed herein.

In various embodiments, the machine 900 comprises processors 910, memory 930, and I/O components 950, which can be configured to communicate with each other via a bus 902. In an example embodiment, the processors 910 (e.g., a central processing unit (CPU), a reduced instruction set computing (RISC) processor, a complex instruction set computing (CISC) processor, a graphics processing unit (GPU), a digital signal processor (DSP), an application specific integrated circuit (ASIC), a radio-frequency integrated circuit (RFIC), another processor, or any suitable combination thereof) include, for example, a processor 912 and a processor 914 that may execute the instructions 916. The term “processor” is intended to include multi-core processors 910 that may comprise two or more independent processors 912, 914 (also referred to as “cores”) that can execute instructions 916 contemporaneously. Although FIG. 17 shows multiple processors 910, the machine 900 may include a single processor 910 with a single core, a single processor 910 with multiple cores (e.g., a multi-core processor 910), multiple processors 912, 914 with a single core, multiple processors 910, 912 with multiples cores, or any combination thereof.

The memory 930 comprises a main memory 932, a static memory 934, and a storage unit 936 accessible to the processors 910 via the bus 902, according to some embodiments. The storage unit 936 can include a machine-readable medium 938 on which are stored the instructions 916 embodying any one or more of the methodologies or functions described herein. The instructions 916 can also reside, completely or at least partially, within the main memory 932, within the static memory 934, within at least one of the processors 910 (e.g., within the processor's cache memory), or any suitable combination thereof, during execution thereof by the machine 900. Accordingly, in various embodiments, the main memory 932, the static memory 934, and the processors 910 are considered machine-readable media 938.

As used herein, the term “memory” refers to a machine-readable medium 938 able to store data temporarily or permanently and may be taken to include, but not be limited to, random-access memory (RAM), read-only memory (ROM), buffer memory, flash memory, and cache memory. While the machine-readable medium 938 is shown, in an example embodiment, to be a single medium, the term “machine-readable medium” should be taken to include a single medium or multiple media (e.g., a centralized or distributed database, or associated caches and servers) able to store the instructions 916. The term “machine-readable medium” shall also be taken to include any medium, or combination of multiple media, that is capable of storing instructions (e.g., instructions 916) for execution by a machine (e.g., machine 900), such that the instructions 916, when executed by one or more processors of the machine 900 (e.g., processors 910), cause the machine 900 to perform any one or more of the methodologies described herein. Accordingly, a “machine-readable medium” refers to a single storage apparatus or device, as well as “cloud-based” storage systems or storage networks that include multiple storage apparatus or devices. The term “machine-readable medium” shall accordingly be taken to include, but not be limited to, one or more data repositories in the form of a solid-state memory (e.g., flash memory), an optical medium, a magnetic medium, other non-volatile memory (e.g., erasable programmable read-only memory (EPROM)), or any suitable combination thereof. The term “machine-readable medium” specifically excludes non-statutory signals per se.

The I/O components 950 include a wide variety of components to receive input, provide output, produce output, transmit information, exchange information, capture measurements, and so on. In general, it will be appreciated that the I/O components 950 can include many other components that are not shown in FIG. 17. The I/O components 950 are grouped according to functionality merely for simplifying the following discussion, and the grouping is in no way limiting. In various example embodiments, the I/O components 950 include output components 952 and input components 954. The output components 952 include visual components (e.g., a display such as a plasma display panel (PDP), a light emitting diode (LED) display, a liquid crystal display (LCD), a projector, or a cathode ray tube (CRT)), acoustic components (e.g., speakers), haptic components (e.g., a vibratory motor), other signal generators, and so forth. The input components 954 include alphanumeric input components (e.g., a keyboard, a touch screen configured to receive alphanumeric input, a photo-optical keyboard, or other alphanumeric input components), point-based input components (e.g., a mouse, a touchpad, a trackball, a joystick, a motion sensor, or other pointing instruments), tactile input components (e.g., a physical button, a touch screen that provides location and force of touches or touch gestures, or other tactile input components), audio input components (e.g., a microphone), and the like.

In some further example embodiments, the I/O components 950 include biometric components 956, motion components 958, environmental components 960, or position components 962, among a wide array of other components. For example, the biometric components 956 include components to detect expressions (e.g., hand expressions, facial expressions, vocal expressions, body gestures, or eye tracking), measure biosignals (e.g., blood pressure, heart rate, body temperature, perspiration, or brain waves), identify a person (e.g., voice identification, retinal identification, facial identification, fingerprint identification, or electroencephalogram based identification), and the like. The motion components 958 include acceleration sensor components (e.g., accelerometer), gravitation sensor components, rotation sensor components (e.g., gyroscope), and so forth. The environmental components 960 include, for example, illumination sensor components (e.g., photometer), temperature sensor components (e.g., one or more thermometers that detect ambient temperature), humidity sensor components, pressure sensor components (e.g., barometer), acoustic sensor components (e.g., one or more microphones that detect background noise), proximity sensor components (e.g., infrared sensors that detect nearby objects), gas sensor components (e.g., machine olfaction detection sensors, gas detection sensors to detect concentrations of hazardous gases for safety or to measure pollutants in the atmosphere), or other components that may provide indications, measurements, or signals corresponding to a surrounding physical environment. The position components 962 include location sensor components (e.g., a Global Positioning System (GPS) receiver component), altitude sensor components (e.g., altimeters or barometers that detect air pressure from which altitude may be derived), orientation sensor components (e.g., magnetometers), and the like.

Communication can be implemented using a wide variety of technologies. The I/O components 950 may include communication components 964 operable to couple the machine 900 to a network 980 or devices 970 via a coupling 982 and a coupling 972, respectively. For example, the communication components 964 include a network interface component or another suitable device to interface with the network 980. In further examples, communication components 964 include wired communication components, wireless communication components, cellular communication components, near field communication (NFC) components, BLUETOOTH® components (e.g., BLUETOOTH® Low Energy), WI-FI© components, and other communication components to provide communication via other modalities. The devices 970 may be another machine 900 or any of a wide variety of peripheral devices (e.g., a peripheral device coupled via a Universal Serial Bus (USB)).

Moreover, in some embodiments, the communication components 964 detect identifiers or include components operable to detect identifiers. For example, the communication components 964 include radio frequency identification (RFID) tag reader components, NFC smart tag detection components, optical reader components (e.g., an optical sensor to detect a one-dimensional bar codes such as a. Universal Product Code (UPC) bar code, multi-dimensional bar codes such as a Quick Response (QR) code, Aztec Code, Data Matrix, Dataglyph, MaxiCode, PDF417, Ultra Code, Uniform Commercial Code Reduced Space Symbology (UCC RSS)-2D bar codes, and other optical codes), acoustic detection components (e.g., microphones to identify tagged audio signals), or any suitable combination thereof. In addition, a variety of information can be derived via the communication components 964, such as location via Internet Protocol (IP) geo-location, location via WI-FI® signal triangulation, location via detecting a BLUETOOTH® or NFC beacon signal that may indicate a particular location, and so forth.

In various example embodiments, one or more portions of the network 980 can be an ad hoc network, an intranet, an extranet, a virtual private network (VPN), a local area network (LAN), a wireless LAN (WLAN), a wide area network (WAN), a wireless WAN (WWAN), a metropolitan area network (MAN), the Internet, a portion of the Internet, a portion of the public switched telephone network (PSTN), a plain old telephone service (POTS) network, a cellular telephone network, a wireless network, a WI-FI® network, another type of network, or a combination of two or more such networks. For example, the network 980 or a portion of the network 980 may include a wireless or cellular network, and the coupling 982 may be a Code Division Multiple Access (CDMA) connection, a Global System for Mobile communications (GSM) connection, or another type of cellular or wireless coupling. In this example, the coupling 982 can implement any of a variety of types of data transfer technology, such as Single Carrier Radio Transmission Technology (1×RTT), Evolution-Data Optimized (EVDO) technology, General Packet Radio Service (GPRS) technology, Enhanced Data rates for GSM Evolution (EDGE) technology, third Generation Partnership Project (3GPP) including 3G, fourth generation wireless (4G) networks, Universal Mobile Telecommunications System (UMTS), High Speed Packet Access (HSPA), Worldwide Interoperability for Microwave Access (WiMAX), Long Term Evolution (LTE) standard, others defined by various standard-setting organizations, other long range protocols, or other data transfer technology.

In example embodiments, the instructions 916 are transmitted or received over the network 980 using a transmission medium via a network interface device (e.g., a network interface component included in the communication components 964) and utilizing any one of a number of well-known transfer protocols (e.g., Hypertext Transfer Protocol (HTTP)). Similarly, in other example embodiments, the instructions 916 are transmitted or received using a transmission medium via the coupling 972 (e.g., a peer-to-peer coupling) to the devices 970. The term “transmission medium” shall be taken to include any intangible medium that is capable of storing, encoding, or carrying the instructions 916 for execution by the machine 900, and includes digital or analog communications signals or other intangible media to facilitate communication of such software.

Furthermore, the machine-readable medium 938 is non-transitory (in other words, not having any transitory signals) in that it does not embody a propagating signal. However, labeling the machine-readable medium 938 “non-transitory” should not be construed to mean that the medium is incapable of movement; the medium 938 should be considered as being transportable from one physical location to another. Additionally, since the machine-readable medium 938 is tangible, the medium 938 may be considered to be a machine-readable device.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

What is claimed is:

1. A method comprising:
retrieving, by a server computer, raw data received from one or more client devices;
aggregating, by the server computer, the raw data to create aggregated raw data;
adding, by the server computer, the aggregated raw data to previously aggregated data to create aggregated data;
generating, by the server computer, heat map data from the aggregated data;
compressing, by the server computer, the heat map data; and
storing, by the server computer, the compressed heat map data.

2. The method of claim 1, wherein before retrieving the raw data received from the one or more client devices, the method further comprises:
receiving the raw data from the one or more client devices;
decompressing the raw data received from the one or more client devices; and
storing the decompressed raw data in an analytics database.

3. The method of claim 1, wherein the raw data received from the one or more client devices comprises at least one of a group comprising: head position information, head orientation information, and depth information.

4. The method of claim 1, wherein the raw data is associated with a plurality of virtual reality applications, and wherein aggregating the raw data to create aggregated raw data further comprises creating a hierarchical structure for each of the plurality of virtual reality applications.

5. The method of claim 4, wherein the hierarchical structure for each of the plurality of virtual reality applications includes one or more scenes.

6. The method of claim 1, wherein generating the heat map data from the aggregated data further comprises:
accumulating each of a plurality of user head positions in a four dimensional matrix, wherein three dimensions correspond to a position in a virtual world, and a fourth dimension corresponds to a time at the position.

7. The method of claim 1, wherein generating the heat map data from the aggregated data further comprises:
accumulating a view of each of a plurality of users onto a cube map matrix.

8. The method of claim 1, wherein generating the heat map data from the aggregated data further comprises:
encoding each frame of a virtual world associated with a virtual reality application with an octree representation.

9. The method of claim 1, further comprising:
receiving, at the server computer, a request for heat map data; and
providing, by the server computer, heat map data in response to the request.

10. A server computer comprising:
a processor; and
a computer readable medium coupled with the processor, the computer readable medium comprising instructions stored thereon that are executable by the processor to cause a computing device to:
retrieve raw data received from one or more client devices;
aggregate the raw data to create aggregated raw data;
add the aggregated raw data to previously aggregated data, creating aggregated data;
generate heat map data from the aggregated data;
compress the heat map data; and
store the compressed heat map data.

11. The server computer of claim 10, wherein before retrieving the raw data received from the one or more client devices, the computer readable medium further comprises instructions stored thereon that are executable by the processor to cause the computing device to:
receive the raw data from the one or more client devices;
decompress the raw data received from the one or more client devices; and
store the decompressed raw data in an analytics database.

12. The server computer of claim 10, wherein the raw data received from the one or more client devices comprises at least one of a group comprising: head position information, head orientation information, and depth information.

13. The server computer of claim 10, wherein the raw data is associated with a plurality of virtual reality applications, and wherein aggregating the raw data to create aggregated raw data further comprises creating a hierarchical structure for each of the plurality of virtual reality applications.

14. The server computer of claim 13, wherein the hierarchical structure for each of the plurality of virtual reality applications includes one or more scenes.

15. The server computer of claim 10, wherein generating the heat map data from the aggregated data further comprises:
accumulating each of a plurality of user head positions in a four dimensional matrix, wherein three dimensions correspond to a position in a virtual world, and a fourth dimension corresponds to a time at the position.

16. The server computer of claim 10, wherein generating the heat map data from the aggregated data further comprises:
accumulating a view of each of a plurality of users onto a cube map matrix.

17. The server computer of claim 10, wherein generating the heat map data from the aggregated data further comprises:
encoding each frame of a virtual world associated with a virtual reality application with an octree representation.

18. The server computer of claim 10, wherein the computer readable medium further comprises instructions stored thereon that are executable by the processor to cause a computing device to:
receive a request for heat map data; and
provide heat map data in response to the request.

19. A non-transitory computer readable medium comprising instructions stored thereon that are executable by at least one processor to cause a computing device to:
retrieve raw data received from one or more client devices;
aggregate the raw data to create aggregated raw data;
add the aggregated raw data to previously aggregated data, creating aggregated data;
generate heat map data from the aggregated data;
compress the heat map data; and
store the compressed heat map data.

20. The non-transitory computer readable medium of claim 19, further comprising instructions stored thereon that are executable by the at least one processor to cause the computing device to:
receive a request for heat map data; and
provide heat map data in response to the request.
